(19) United States
(12) Patent Application Publication
(10) Pub. No.: US 2025/0112284 A1
(43) Pub. Date: Apr. 3, 2025

(54) BATTERY CONTROL DEVICE, BATTERY MONITORING SYSTEM INCLUDING BATTERY CONTROL DEVICE AND BATTERY MONITORING DEVICES, AND METHOD OF IDENTIFYING ABNORMAL BATTERY USING BATTERY MONITORING SYSTEM

(71) Applicant: DENSO CORPORATION, Kariya-city (JP)

(72) Inventors: Yuto HONDA, Kariya-city (JP); Sho MATSUMOTO, Kariya-city (JP); Yoshimitsu INOUE, Kariya-city (JP); Hideki MORISHIMA, Kariya-city (JP); Kohki OHBA, Kariya-city (JP); Ryu ATSUTA, Kariya-city (JP); Tomohisa KISHIGAMI, Kariya-city (JP); Youichi HAYASE, Kariya-city (JP)

(73) Assignee: DENSO CORPORATION, Kariya-city (JP)

(21) Appl. No.: 18/978,646

(22) Filed: Dec. 12, 2024

Related U.S. Application Data
(63) Continuation of application No. PCT/JP2023/020525, filed on Jun. 1, 2023.

(30) Foreign Application Priority Data
Jun. 17, 2022 (JP) 2022-098017

(51) Int. Cl. H01M 10/42; G01R 31/371; G01R 31/382

(52) U.S. Cl. CPC H01M 10/425; G01R 31/371; G01R 31/382; H01M 10/4207; H01M 2010/4271; H01M 2010/4278; H01M 2220/20

(57) ABSTRACT

A battery control device includes a parent-device-side storage unit, a parent-device-side communication unit and an identification unit. The parent-device-side storage unit is configured to store parameters related to communication quality of wireless communication between the battery monitoring devices and the battery control device when batteries, battery monitoring devices and the battery control device are arranged in a predetermined arrangement state in an accommodation section; the parameters are associated respectively with the battery monitoring devices. The parent-device-side communication unit is configured to perform the wireless communication with the battery monitoring devices. The identification unit is configured to identify, based on radio signals received from the battery monitoring devices by the parent-device-side communication unit and the parameters stored in the parent-device-side storage unit, the batteries monitored respectively by the battery monitoring devices that are respectively transmission sources of the received radio signals.

### CROSS-REFERENCE TO RELATED APPLICATIONS

The present application is a continuation application of International Application No. PCT/JP2023/020525 filed on Jun. 1, 2023, which is based on and claims priority from Japanese Patent Application No. 2022-098017, filed on Jun. 17, 2022. The entire contents of these applications are incorporated by reference into the present application.

### BACKGROUND

### 1 Technical Field

The present disclosure relates to a battery control device, a battery monitoring system that includes the battery control device and battery monitoring devices, and a method of identifying an abnormal battery using the battery monitoring system.

### 2 Description of Related Art

There is known, for example as disclosed in International Publication No. WO 2013/051157 A1, a battery monitoring system that monitors the states of a plurality of cell groups constituting a battery module. Specifically, the battery monitoring system includes a plurality of battery monitoring devices and a battery control device. The battery monitoring devices are provided individually to respectively correspond to the cell groups and monitor the states of the corresponding cell groups. The battery control device acquires, by performing wireless communication between it and the battery monitoring devices, battery information indicative of the monitoring results from the battery monitoring devices. Then, the battery control device performs various controls on the basis of the acquired battery information.

In order to perform the wireless communication between the battery control device and the battery monitoring devices, each of the battery monitoring devices is given unique identification information. Moreover, each of the battery monitoring devices wirelessly transmits, to the battery control device, the identification information along with the battery information. Consequently, the battery control device can determine which of the battery monitoring devices has transmitted the battery information.

Since the cell groups are connected in series with each other, there is a relationship between them such that the further the cell groups are located on the higher potential side, the higher the potentials of the cell groups relative to the ground potential become. Based on this relationship, the battery control device ascertains the correspondence between the battery monitoring devices and the cell groups that are monitored respectively by the battery monitoring devices. Specifically, each of battery monitoring devices measures the potential of the corresponding cell group, which is the monitoring target thereof, relative to the ground potential. Then, each of battery monitoring devices wirelessly transmits, to the battery control device, the identification information together with the measured potential of the corresponding cell group. Consequently, the battery control device can ascertain the aforementioned correspondence.

### SUMMARY

Batteries such as cell groups, the battery monitoring devices that respectively monitor the batteries, and the battery control device are generally accommodated in an accommodation section. The accommodation section is configured so that part of it reflects radio waves. Therefore, when the battery monitoring devices transmit radio signals, the transmitted radio signals will be reflected at a wall surface of the accommodation section. As a result, multipath may occur, making it impossible to accurately transmit the measured potentials and the identification information from the battery monitoring devices to the battery control device. In this case, it will become impossible for the battery control device to ascertain the correspondence between the battery monitoring devices and the batteries that are monitored respectively by the battery monitoring devices.

The present disclosure has been accomplished in view of the above problem.

According to the present disclosure, there is provided a battery control device applicable to a battery monitoring system. The battery monitoring system includes a plurality of battery monitoring devices provided individually to respectively correspond to a plurality of batteries and monitor states of the corresponding batteries. The battery control device is configured to be arranged, together with the batteries and the battery monitoring devices, in a predetermined arrangement state in an accommodation section. The accommodation section is configured so that at least part of it reflects radio waves. The battery control device includes: a parent-device-side storage unit configured to store parameters related to communication quality of wireless communication between the battery monitoring devices and the battery control device when the batteries, the battery monitoring devices and the battery control device are arranged in the predetermined arrangement state in the accommodation section, the parameters being associated respectively with the battery monitoring devices; a parent-device-side communication unit configured to perform the wireless communication with the battery monitoring devices; and an identification unit configured to perform an identification process of identifying, based on radio signals received from the battery monitoring devices by the parent-device-side communication unit and the parameters stored in the parent-device-side storage unit, the batteries monitored respectively by the battery monitoring devices that are respectively transmission sources of the received radio signals.

In the above battery control device according to the present disclosure, the parameters are information on the communication quality of the wireless communication between the battery monitoring devices and the battery control device when the batteries, the battery monitoring devices and the battery control device are arranged in the predetermined arrangement state in the accommodation section. Moreover, the parameters are associated respectively with the battery monitoring devices. Therefore, the parameters are also information for identifying, for each of the battery monitoring devices, which of the batteries is monitored by the battery monitoring device when the predetermined arrangement state is realized.

In view of the above, the identification unit of the battery control device according to the present disclosure is configured to perform the identification process of identifying, based on the radio signals received from the battery monitoring devices by the parent-device-side communication unit and the parameters stored in the parent-device-side storage unit, the batteries monitored respectively by the battery monitoring devices that are respectively the transmission sources of the received radio signals. Consequently, in the accommodation space where multipath may occur, the battery control device can still ascertain the correspondence between the battery monitoring devices and the batteries that are monitored respectively by the battery monitoring devices.

### BRIEF DESCRIPTION OF THE DRAWINGS

FIG. 1 is a configuration diagram of a vehicle according to a first embodiment.

FIG. 2 is a block diagram illustrating the overall configuration of a battery pack according to the first embodiment.

FIG. 3 is a perspective view illustrating the manner of arranging battery blocks and the like in a housing according to the first embodiment.

FIG. 4 is a cross-sectional view taken along the line 4-4 in FIG. 3.

FIGS. 5A and 5B are perspective views respectively illustrating two alternative manners of arranging battery cells that constitute a battery block.

FIG. 6 is an explanatory diagram illustrating transmitting and receiving antennas placed in an environment where radio waves are not reflected.

FIG. 7 is a graph illustrating the frequency characteristics of the strengths of radio signals received in the environment where radio waves are not reflected.

FIG. 8 is an explanatory diagram illustrating transmitting and receiving antennas placed in an environment where radio waves are reflected.

FIG. 9 is a graph illustrating the frequency characteristics of the strengths of radio signals received in the environment where radio waves are reflected.

FIG. 10 is an explanatory diagram illustrating a state in which a measurement device is connected to the battery pack.

FIG. 11 is a graph illustrating the frequency characteristics of the strengths of radio signals associated respectively with battery monitoring devices.

FIG. 12 is a graph illustrating an example of measurement results of the strength of a radio signal.

FIG. 13 is a flowchart illustrating the steps of a process of identifying monitoring targets.

FIG. 14 is a flowchart illustrating a method of identifying a battery block in which an abnormality has occurred.

FIG. 15 is a perspective view illustrating the manner of arranging battery blocks and the like in a housing according to a modification of the first embodiment.

FIG. 16 is a flowchart illustrating the steps of a process of identifying monitoring targets according to a second embodiment.

FIG. 17 is a flowchart illustrating the steps of a storage process in a battery monitoring device.

FIG. 18 is a flowchart illustrating the steps of a process of identifying monitoring targets according to a third embodiment.

FIG. 19 is a plan view of a battery pack according to a fourth embodiment, wherein a cover has been removed from the battery pack.

FIG. 20 is a graph illustrating the frequency characteristics of the strengths of radio signals associated respectively with battery monitoring devices according to the fourth embodiment.

FIG. 21 is a plan view of a battery pack according to a comparative example, wherein a cover has been removed from the battery pack.

FIG. 22 is a graph illustrating the frequency characteristics of the strengths of radio signals associated respectively with battery monitoring devices according to the comparative example.

FIG. 23 is a plan view of a battery pack according to a fifth embodiment, wherein a cover has been removed from the battery pack.

FIG. 24 is a plan view of a battery pack according to a modification of the fifth embodiment, wherein a cover has been removed from the battery pack.

FIG. 25 is a plan view of a battery pack according to a sixth embodiment, wherein a cover has been removed from the battery pack.

FIGS. 26A and 26B are graphs illustrating the frequency characteristics of the strengths of radio signals before switching the directivity of a child-device-side antenna from A to B.

FIGS. 27A and 27B are graphs illustrating the frequency characteristics of the strengths of radio signals after switching the directivity of the child-device-side antenna from A to B.

FIGS. 28A and 28B are explanatory diagrams illustrating an example of a child-device-side antenna whose directivity can be changed.

FIGS. 29A and 29B are explanatory diagrams illustrating another example of a child-device-side antenna whose directivity can be changed.

FIG. 30 is a perspective view illustrating a normal arrangement of battery blocks according to a seventh embodiment.

FIG. 31 is a perspective view illustrating a state in which the arrangement position of one of the battery blocks is deviated from a normal arrangement position.

FIG. 32 is a graph illustrating the frequency characteristics of the strength of a radio signal transmitted from a battery block when the battery block is at a normal arrangement position and when the battery block is at an abnormal arrangement position.

FIG. 33 is a flowchart illustrating the steps of a process of identifying monitoring targets according to the seventh embodiment.

FIG. 34 is a graph illustrating the frequency characteristics of reference strengths of radio signals according to an eighth embodiment.

FIG. 35 is a flowchart illustrating the steps of a process of identifying monitoring targets according to the eighth embodiment.

FIG. 36 is a flowchart illustrating the steps of a process of identifying monitoring targets according to a ninth embodiment.

FIG. 37 is a flowchart illustrating the steps of a process of identifying monitoring targets according to a tenth embodiment.

FIG. 38 is a graph illustrating the frequency characteristics of reference strengths of radio signals according to an eleventh embodiment.

FIG. 39 is a flowchart illustrating the steps of a process of identifying monitoring targets according to the eleventh embodiment.

FIG. 40 is an explanatory diagram illustrating the manner of arranging a battery pack in an accommodation section within a chassis of a vehicle according to a twelfth embodiment.

FIG. 41 is a cross-sectional view taken along the line 41-41 in FIG. 40.

FIG. 42 is a cross-sectional view of a battery pack according to a thirteenth embodiment.

FIG. 43 is a cross-sectional view of a battery pack according to a fourteenth embodiment.

FIG. 44 is an explanatory diagram illustrating the manner of arranging battery blocks and the like in an accommodation section within a chassis of a vehicle according to a fifteenth embodiment.

FIG. 45 is a perspective view illustrating the manner of arranging battery cells according to a modification.

### DESCRIPTION OF EMBODIMENTS

Embodiments will now be described with reference to the drawings. It should be noted that in the embodiments, functionally and/or structurally corresponding and/or associated parts will be designated by the same reference signs as appropriate. Moreover, it also should be noted that for corresponding and/or associated parts in one embodiment, reference may be made to the explanation in the other embodiments.

### First Embodiment

Hereinafter, a first embodiment embodying a battery monitoring system according to the present disclosure will be described with reference to the drawings. The battery monitoring system is installed in a vehicle that employs a rotating electric machine as a traveling power source, such as an electric vehicle or a hybrid vehicle.

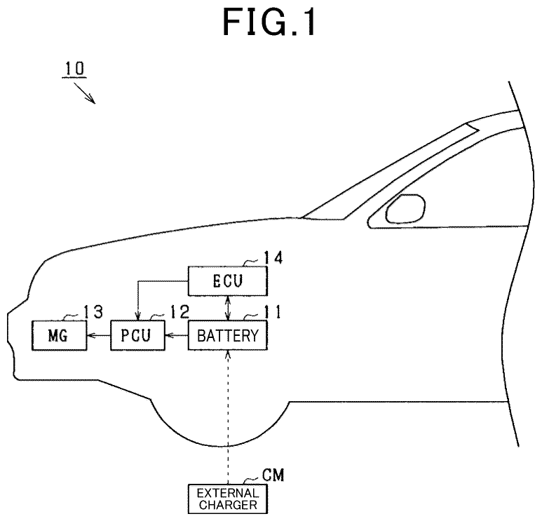

FIG. 1 is a schematic diagram illustrating the configuration of a vehicle 10. The vehicle 10 includes a battery pack 11 (denoted by BATTERY in FIG. 1), a Power Control Unit (PCU) 12, a motor 13 (denoted by MG in FIG. 1), and a vehicle ECU 14 (denoted by ECU in FIG. 1).

The battery pack 11 is installed in the vehicle 10 as a drive power source of the vehicle 10. Specifically, in the vehicle 10, the battery pack 11 may be installed, for example, in an engine compartment, in a luggage compartment, under a seat or under the floor. The vehicle 10 travels using electric power stored in the battery pack 11.

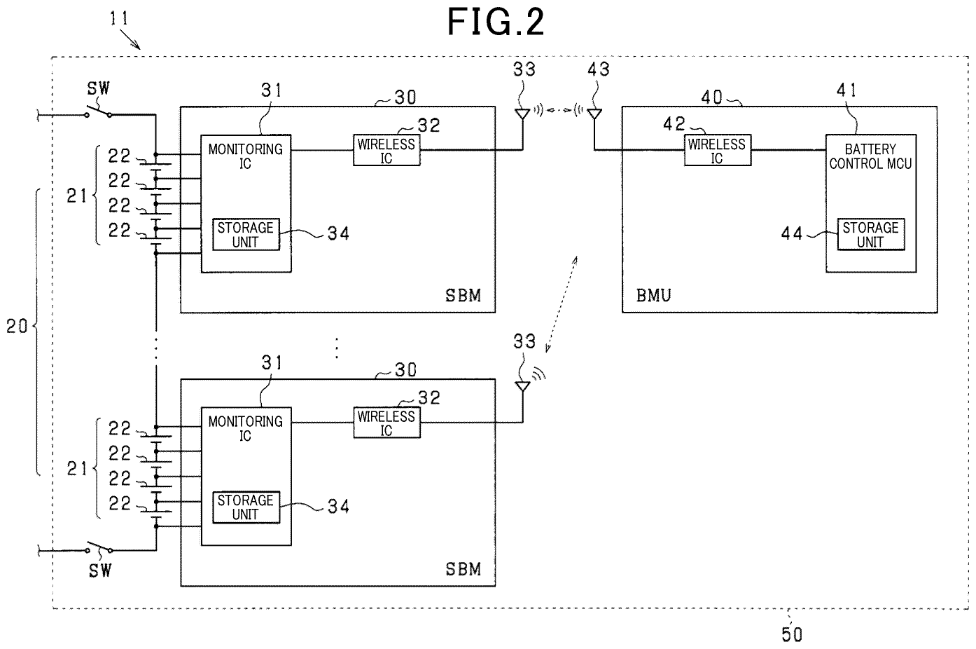

As shown in FIG. 2, the battery pack 11 includes an assembled battery 20 that is constituted of a plurality of battery cells 22 (more particularly, secondary battery cells) connected in series with each other. In the assembled battery 20, there is stored electric power for driving the motor 13. The assembled battery 20 can supply electric power to the motor 13 through the PCU 12. Moreover, during the regenerative power generation by the motor 13 when the vehicle 10 is braked, the assembled battery 20 can receive, through the PCU 12, electric power generated by the motor 13 and be charged with the received electric power. Furthermore, as shown in FIG. 1, the assembled battery 20 is connectable to an external charger CM provided outside the vehicle 10. The external charger CM may be, for example, stationary equipment. The assembled battery 20 can be charged by the external charger CM.

The PCU 12 performs bidirectional electric power conversion between the battery pack 11 and the motor 13 according to control signals from the vehicle ECU 14. The PCU 12 includes an inverter that drives the motor 13 and a converter that boosts a DC voltage supplied to the inverter to a level higher than or equal to the output voltage of the battery pack 11.

The motor 13 is an AC rotating electric machine. The motor 13 may be implemented by, for example, a three-phase AC synchronous motor which has permanent magnets embedded in a rotor. The motor 13 is driven by the PCU 12 to generate a rotational drive force; and the drive force generated by the motor 13 is transmitted to driving wheels of the vehicle 10. On the other hand, during braking of the vehicle 10, the motor 13 operates as an electric generator and performs regenerative power generation. The electric power generated by the motor 13 is supplied to the battery pack 11 through the PCU 12, and stored in the assembled battery 20 in the battery pack 11.

The vehicle ECU 14 includes a CPU, a ROM, a RAM, and input/output ports for inputting/outputting various signals. The CPU deploys programs stored in the ROM to the RAM and executes them. The programs stored in the ROM describe processes of the vehicle ECU 14. For example, as a main process, the vehicle ECU 14 receives, from the battery pack 11, information such as the voltage, current and SOC (State of Charge) of the assembled battery 20; then the vehicle ECU 14 controls drive of the motor 13 and charge/discharge of the battery pack 11 by controlling the PCU 12 based the received information.

FIG. 2 is a schematic diagram illustrating the configuration of the battery pack 11. The battery pack 11 includes the assembled battery 20, a plurality of battery monitoring devices 30, a battery control device 40, and a housing 50 (represented by dashed lines in FIG. 2) that accommodates the aforementioned components.

The assembled battery 20 includes a plurality of battery blocks 21 connected in series with each other. The battery blocks 21 may also be referred to as battery stacks or battery modules. Moreover, each of the battery blocks 21 includes a plurality of battery cells 22. Each of the battery cells 22 may be implemented by, for example, a lithium-ion secondary battery, a nickel-metal hydride secondary battery or the like. In addition, lithium-ion secondary batteries are secondary batteries which use lithium ions as charge carriers. Lithium-ion secondary batteries may include not only general lithium-ion secondary batteries whose electrolyte is a liquid, but also so-called solid-state batteries that use a solid electrolyte. Each of the battery blocks 21 is formed by connecting the battery cells 22 in series with one another. It should be noted that: the assembled battery 20 may alternatively include a plurality of series connection units each of which consists of a plurality of battery blocks 21 connected in series with each other; and the series connection units may be connected in parallel with each other. The PCU 12 is connected with the assembled battery 20 via switches SW (e.g., relays) and wiring 16.

The battery monitoring devices 30 are also called Satellite Battery Modules (SBMs). In each of the battery blocks 21, there is provided a corresponding one of the battery monitoring devices 30. As shown in FIG. 2, each of the battery monitoring devices 30 includes a monitoring IC 31 as a monitoring unit, a child-device-side wireless IC 32 as a wireless control unit, and a child-device-side antenna 33 as a wireless antenna. The child-device-side wireless IC 32 and the child-device-side antenna 33 together constitute a “child-device-side communication unit” of the battery monitoring device 30. The monitoring IC 31, which is also called a Cell Supervising Circuit (CSC), acquires battery information from the battery cells 22 constituting the battery block 21 or from a sensor (not shown). The battery information may include, for example, voltage information, temperature information and current information of the battery cells 22. Moreover, the monitoring IC 31 performs a self-diagnosis and generates self-diagnosis information. The self-diagnosis information may be, for example, information related to the operation check of the battery monitoring device 30, i.e., information related to an abnormality or failure of the battery monitoring device 30. More specifically, the self-diagnosis information is information related to the operation check of the monitoring IC 31 and the child-device-side wireless IC 32 that constitute the battery monitoring device 30.

The child-device-side wireless IC 32 is connected with the monitoring IC 31 in a wired manner. The child-device-side wireless IC 32 includes a wireless MCU (Micro Control Unit) and an RF device (or high-frequency device module). The child-device-side wireless IC 32 wirelessly transmits, via the child-device-side antenna 33, data (including control signals) received from the monitoring IC 31. Moreover, the child-device-side wireless IC 32 sends data, which is received via the child-device-side antenna 33, to the monitoring IC 31.

The monitoring IC 31 includes a child-device-side storage unit 34. The child-device-side storage unit 34 is a non-transitory tangible recording medium other than a ROM (e.g., a non-volatile memory other than a ROM).

The battery control device 40 is also called a battery ECU or BMU (Battery Management Unit). The battery control device 40 is configured so that it can wirelessly communicate with each of the battery monitoring devices 30. Specifically, as shown in FIG. 2, the battery control device 40 includes a battery control MCU 41 as a battery control unit, a parent-device-side wireless IC 42 as a wireless control unit, and a parent-device-side antenna 43 as a wireless antenna. The parent-device-side wireless IC 42 and the parent-device-side antenna 43 together constitute a “parent-device-side communication unit” of the battery control device 40. The battery control MCU 41 is configured with a microcomputer which includes a CPU, a ROM, a RAM and input/output interfaces. The CPU of the battery control MCU 41 deploys programs stored in the ROM to the RAM and executes them. The programs stored in the ROM describe processes related to battery control.

For example, as a main process, the battery control MCU 41 commands the battery monitoring devices 30 to acquire and transmit the battery information. Further, based on the battery information received from the battery monitoring devices 30, the battery control MCU 41 monitors the assembled battery 20, the battery blocks 21 and the battery cells 22. Furthermore, based on the monitoring results, the battery control MCU 41 controls the switches SW that switch the assembled battery 20 between a connected state in which it is connected with the PCU 12 and the motor 13 and a disconnected state in which it is disconnected from the PCU 12 and the motor 13. In addition, the battery control MCU 41 may transmit an equalization signal for equalizing the voltages of the battery cells 22.

The parent-device-side wireless IC 42 is connected with the battery control MCU 41 in a wired manner. Similar to the child-device-side wireless IC 32, the parent-device-side wireless IC 42 includes a wireless MCU and an RF device. The parent-device-side wireless IC 42 wirelessly transmits, via the parent-device-side antenna 43, data received from the battery control MCU 41. Moreover, the parent-device-side wireless IC 42 sends data, which is received via the parent-device-side antenna 43, to the battery control MCU 41. In addition, the parent-device-side antenna 43 and the child-device-side antenna 33 may each be implemented by, for example, a dipole antenna, a Yagi antenna, a slot antenna, an inverted-F antenna, an inverted-L antenna, a chip antenna or a zeroth-order antenna (e.g., a zeroth-order resonant antenna).

The battery control MCU 41 includes a parent-device-side storage unit 44. The parent-device-side storage unit 44 is a non-transitory tangible recording medium other than a ROM (e.g., a non-volatile memory other than a ROM).

The battery monitoring system is constituted of the assembled battery 20, the battery monitoring devices 30, the battery control device 40, and the housing 50 that accommodates the aforementioned components.

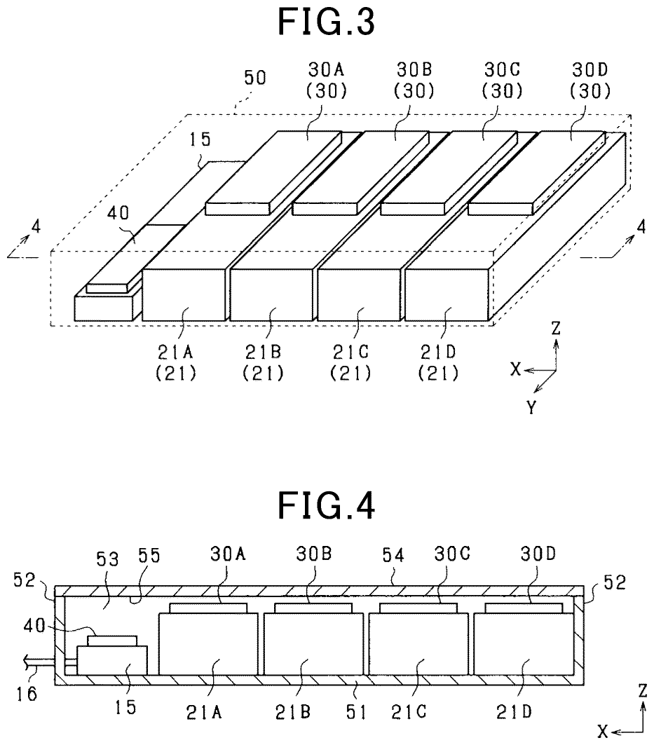

Next, referring to FIGS. 3 and 4, explanation will be given of the housing 50 and the arrangement of the battery blocks 21 and the like in the housing 50. FIG. 4 is a cross-sectional view taken along the line 4-4 in FIG. 3. It should be noted that for the sake of convenience, hatching indicating cross sections is omitted from some of the components shown in FIG. 4.

The housing 50 includes a bottom plate portion 51 and wall portions formed along a peripheral edge of the bottom plate portion 51. The bottom plate portion 51 has a rectangular shape. The wall portions include a pair of first wall portions 52 extending in a lateral direction of the bottom plate portion 51 and a pair of second wall portions 53 extending in a longitudinal direction of the bottom plate portion 51.

Moreover, the housing 50 also includes a cover 54. The cover 54 covers the first wall portions 52 and the second wall portions 53 from above. The cover 54 is removable from a base part of the housing 50 which is constituted of the bottom plate portion 51 and the wall portions. An accommodation section 55 is formed by interior surfaces of the bottom plate portion 51, the first wall portions 52, the second wall portions 53 and the cover 54. The accommodation section 55 has a continuous space in which the battery blocks 21, the battery monitoring devices 30 and the battery control device 40 are accommodated in a predetermined arrangement state.

In the present embodiment, the bottom plate portion 51, the first wall portions 52, the second wall portions 53 and the cover 54 are configured to have an electromagnetic shielding effect of blocking or absorbing radio waves. Specifically, the bottom plate portion 51, the first wall portions 52, the second wall portions 53 and the cover 54 may be formed of, for example, a metal material (such as aluminum) to have an electromagnetic shielding effect.

In the present embodiment, the housing 50 is formed in a rectangular parallelepiped shape and installed in the vehicle 10 such that a longitudinal direction of the housing 50 coincides with a longitudinal direction of the vehicle 10. In FIGS. 3, 4 and the like, an X direction represents the longitudinal direction of the housing 50 (i.e., the longitudinal direction of the vehicle 10); a Y direction represents a lateral direction of the housing 50 (i.e., lateral direction of the vehicle 10); and a Z direction represents a height direction of the housing 50 (i.e., height direction of the vehicle 10). For example, a lower surface of the bottom plate portion 51 may serve as an installation surface to the body of the vehicle 10.

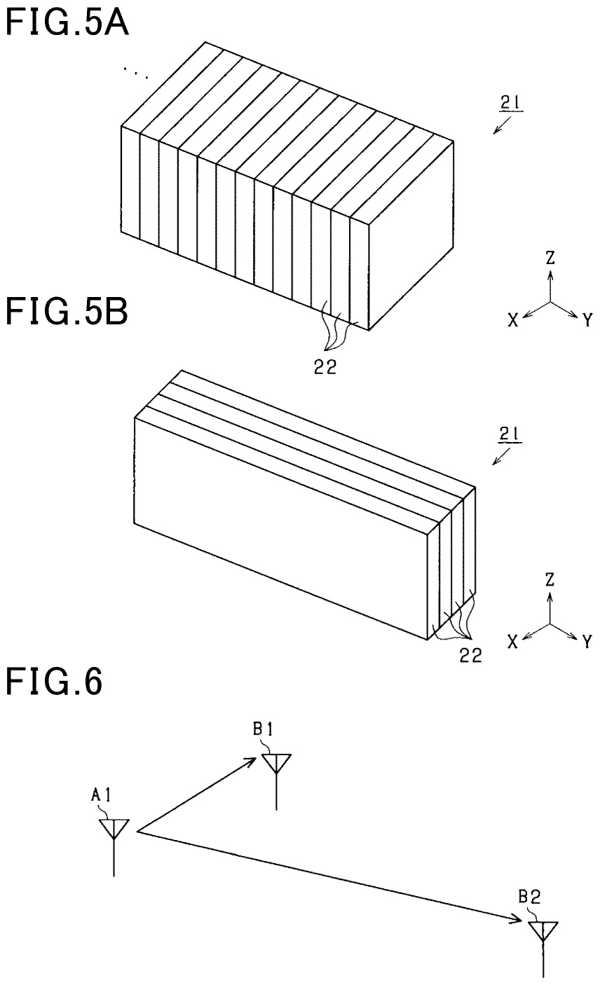

Each of the battery blocks 21 is formed in a rectangular parallelepiped shape and constituted of a plurality of battery cells 22 that are connected in series with each other. In the present embodiment, each of the battery cells 22 has a flat rectangular parallelepiped shape. Moreover, as shown in FIG. 5A, in each of the battery blocks 21, the battery cells 22 are stacked side by side in the lateral direction of the housing 50. Alternatively, as shown in FIG. 5B, in each of the battery blocks 21, the battery cells 22 may be stacked side by side in the longitudinal direction of the housing 50. Moreover, in each of the battery blocks 21, the battery cells 22 may alternatively be connected in parallel with each other.

As shown in FIGS. 3 and 4, each of the battery blocks 21 is arranged on the bottom plate portion 51 of the housing 50 such that the longitudinal direction of each of the battery blocks 21 coincides with the lateral direction of the housing 50. In the present embodiment, for the sake of convenience, it is assumed that there are four battery blocks 21 accommodated in the housing 50. Accordingly, it is also assumed that there are four battery monitoring devices 30 accommodated in the housing 50. Hereinafter, the four battery blocks 21 will be respectively referred to as the first to fourth battery blocks 21A to 21D; and the four battery monitoring devices 30 will be respectively referred to as the first to fourth battery monitoring devices 30A to 30D. It should be noted that the illustration of busbars electrically connecting positive-electrode and negative-electrode terminals of adjacent battery cells 22 in each of the battery blocks 21 is omitted from FIGS. 3 and 4.

In the accommodation section 55, there is a junction box 15 arranged on the bottom plate portion 51. The junction box 15 has a rectangular parallelepiped shape and accommodates the switches SW therein. Moreover, the junction box 15 is arranged next to the first battery block 21A such that the longitudinal direction of the junction box 15 is parallel to the longitudinal direction of each of the battery blocks 21. In addition, the height dimension of the junction box 15 is less than the height dimension of each of the battery blocks 21.

The battery control device 40 is arranged on an upper surface of the junction box 15. On the other hand, the battery monitoring devices 30 are arranged respectively on upper surfaces of the battery blocks 21. In the accommodation section 55, the arrangement position of the battery control device 40 is lower than the arrangement position of each of the battery monitoring devices 30.

Each of the first to fourth battery monitoring devices 30A to 30D has unique identification information assigned thereto and stored in the child-device-side storage unit 34 thereof. When transmitting the battery information to the battery control device 40, each of the first to fourth battery monitoring devices 30A to 30D transmits the identification information assigned thereto along with the battery information. Consequently, the battery control device 40 can determine which of the battery monitoring devices 30 has transmitted the battery information.

Next, explanation will be given of a method by which the battery control device 40 identifies, for each of the first to fourth battery monitoring devices 30A to 30D, which of the battery blocks 21 is monitored by the battery monitoring device.

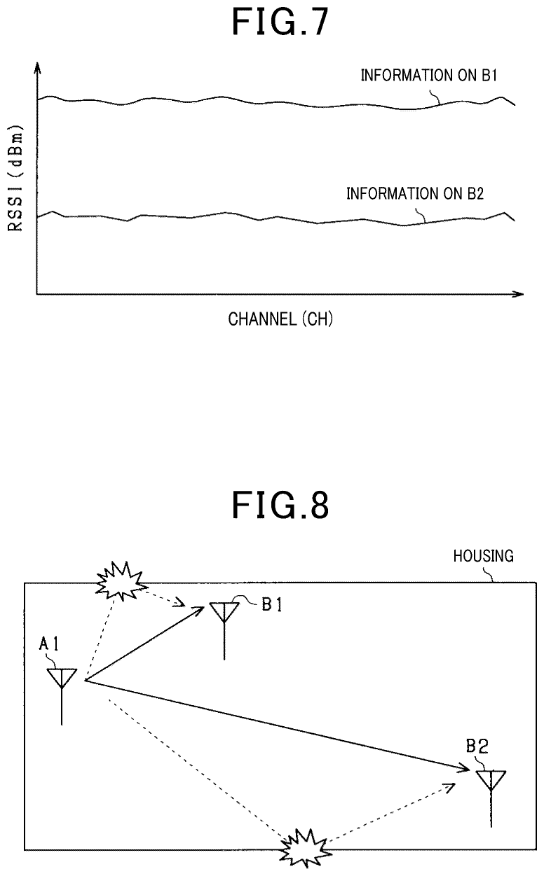

FIG. 6 illustrates a transmitting antenna A1 and first and second receiving antennas B1 and B2, which are placed in an environment where radio waves are not reflected. When a radio signal is transmitted by the transmitting antenna A1, the strength of the radio signal received by the first and second receiving antennas B1 and B2 has frequency characteristics as shown in FIG. 7. Specifically, as shown in FIG. 7, the signal strength decreases due to attenuation as the distance from the transmitting antenna A1 increases. In this case, the signal strength is almost independent of frequency. Therefore, by measuring the magnitude of the signal strength, it is possible to identify that one of the battery monitoring devices 30 which has transmitted the signal and thus possible to identify that one of the battery blocks 21 which is monitored by the identified battery monitoring device 30.

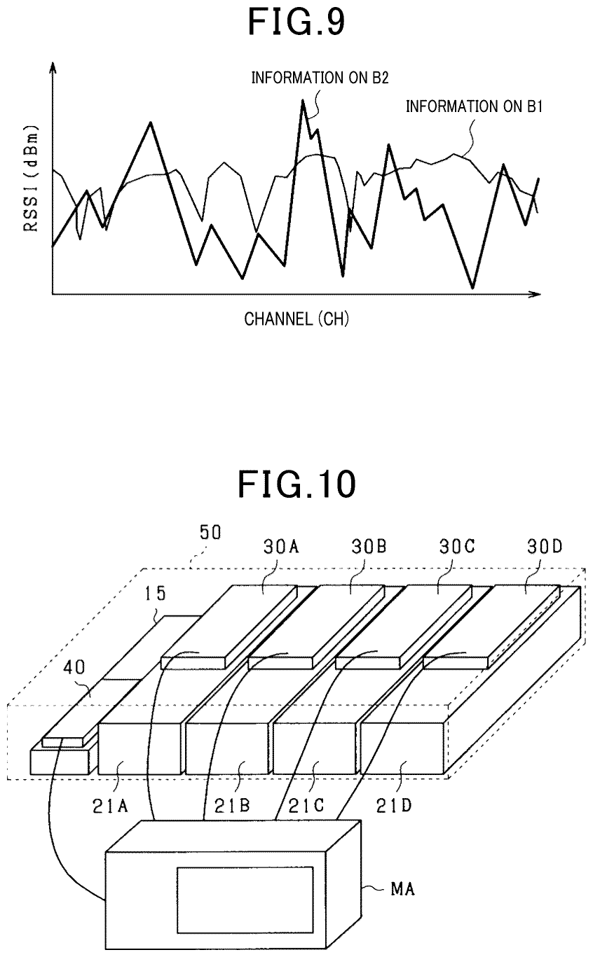

FIG. 8 illustrates a transmitting antenna A1 and first and second receiving antennas B1 and B2, which are placed in a housing. When a radio signal is transmitted by the transmitting antenna A1, the transmitted signal is diffusely reflected within the housing. As a result, multipath occurs and thus the strength of the radio signal received by the first and second receiving antennas B1 and B2 has frequency characteristics as shown in FIG. 9. Specifically, as shown in FIG. 9, the signal strength does not decrease due to attenuation as the distance from the transmitting antenna A1 increases. For example, depending on the frequency, a significant drop may occur in the received power. Therefore, the strength of a signal received from one battery monitoring device 30 which is located further from the battery control device 40 may become higher than the strength of a signal received from another battery monitoring device 30 which is located closer to the battery control device 40. That is, in a space where diffuse reflection occurs, depending on the frequency, there is no longer a proportional relationship between the distance between the transmitting antenna and the receiving antenna and the amount of attenuation of the received signal. Therefore, it is difficult to identify, through only a simple comparison of the signal strength, that one of the battery monitoring devices 30 which has transmitted the signal.

In view of the above, in the present embodiment, in the manufacturing process of the battery pack 11, the frequency characteristics of the strengths of radio signals from the battery monitoring devices 30 are measured. Then, based on the correlation coefficients between the measured radio signal strengths and the radio signal strengths measured in advance (e.g., measured at the time of designing the battery pack 11), the battery blocks 21 that are monitored respectively by the battery monitoring devices 30 are identified.

Specifically, first, at the time of designing the battery pack 11 (i.e., at the development stage of the battery pack 11), the battery blocks 21, the battery monitoring devices 30, the battery control device 40 and the junction box 15 are placed in a predetermined arrangement state in the housing 50. The predetermined arrangement state is an arrangement state of the battery blocks 21 and the like in mass-produced battery packs.

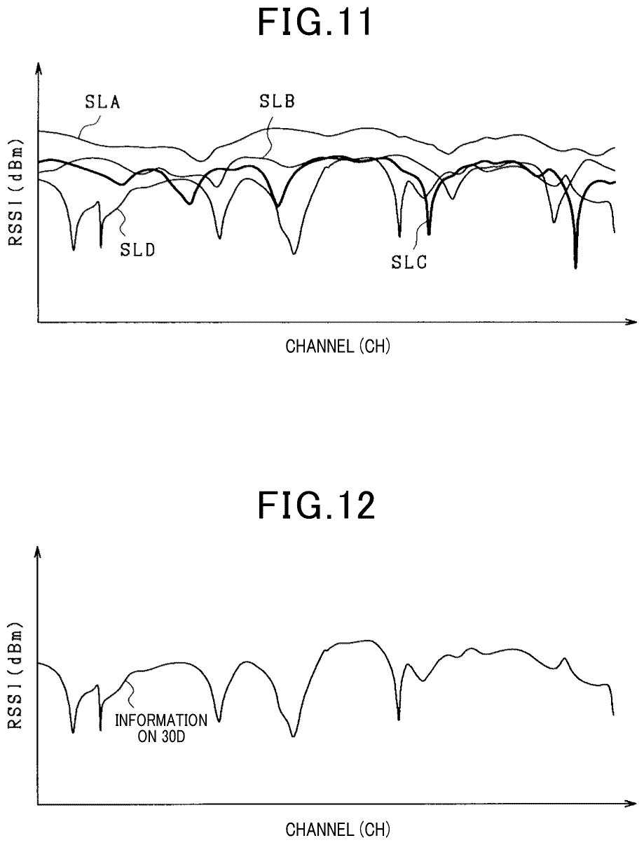

As shown in FIG. 10, after an external measurement device MA is electrically connected to the battery control device 40 (specifically, e.g., to the parent-device-side antenna 43) and the battery monitoring devices 30 (specifically, e.g., to the child-device-side antennas 33), when radio signals are outputted individually from the battery monitoring devices 30, the frequency characteristics of the signal strengths are measured by the external measurement device MA. Specifically, the measurement device MA measures, for each of the battery monitoring devices 30, the power loss (e.g., transmission characteristics) when the radio wave is propagated from the child-device-side antenna 33 of the battery monitoring device 30 to the parent-device-side antenna 43. Then, the measurement device MA calculates, for each of the battery monitoring devices 30, the frequency characteristics of the received power (i.e., the frequency characteristics of the signal strength) at the battery control device 40 by adding the transmitted power from the child-device-side antenna 33 of the battery monitoring device 30 and the power losses in the parent-device-side wireless IC 42, the parent-device-side antenna 43, both the child-device-side wireless IC 32 and the child-device-side antenna 33 of the battery monitoring device 30, etc. to the measured power loss. In FIG. 11, SLA indicates the frequency characteristics of the signal strength when the battery control device 40 receives the radio signal transmitted from the first battery monitoring device 30A; SLB indicates the frequency characteristics of the signal strength when the battery control device 40 receives the radio signal transmitted from the second battery monitoring device 30B; SLC indicates the frequency characteristics of the signal strength when the battery control device 40 receives the radio signal transmitted from the third battery monitoring device 30C; and SLD indicates the frequency characteristics of the signal strength when the battery control device 40 receives the radio signal transmitted from the fourth battery monitoring device 30D. Hereinafter, the frequency characteristics of the signal strengths measured in advance in this manner will be referred to as the reference strengths as appropriate. In addition, for each of the battery monitoring devices 30, it is also possible to: (i) measure the received power by the battery control device 40 instead of using the measurement device MA; (ii) read out the measurement results; and (iii) define the frequency characteristic of the signal strength calculated based on the read-out measurement results as the reference strength of radio signals transmitted from the battery monitoring device 30.

In the manufacturing process of the battery pack 11, a writing device, which is provided to the production line, is electrically connected to the battery pack 11. The writing device stores information on the reference strengths in the parent-device-side storage unit 44 of the battery control device 40. In addition, the information on the reference strengths may be stored in the parent-device-side storage unit 44 by the writing device during the manufacturing process of the battery control device 40 which is a component of the battery pack 11.

In the manufacturing process of the battery pack 11, the first to fourth battery monitoring devices 30A to 30D transmit the radio signals sequentially so that the transmission periods of the radio signals do not overlap one another. FIG. 12 illustrates an example of the strength of a radio signal received by the battery control device 40 when the radio signal is transmitted from the fourth battery monitoring device 30D.

Next, the battery control device 40 performs an identification process. Specifically, in the identification process, the battery control MCU 41 calculates correlation coefficients between the strength of the received signal from a first one of the battery monitoring devices 30 and the first to fourth reference strengths SLA to SLD associated respectively with the first to fourth battery monitoring devices 30A to 30D. Then, the battery control MCU 41 identifies the battery block 21 that is monitored by the battery monitoring device 30 associated with the reference strength used for the calculation of a maximum correlation coefficient among the four calculated correlation coefficients as the monitoring target of the battery monitoring device 30 that is the transmission source of the radio signal used for the calculation of the maximum correlation coefficient.

For example, assume that for the first received signal, the correlation coefficient with the first reference strength SLA associated with the first battery monitoring device 30A is 0.3; the correlation coefficient with the second reference strength SLB associated with the second battery monitoring device 30B is 0.5; the correlation coefficient with the third reference strength SLC associated with the third battery monitoring device 30C is 0.4; and the correlation coefficient with the fourth reference strength SLD associated with the fourth battery monitoring device 30D is 0.7. In this case, the maximum correlation coefficient is 0.7. Therefore, the battery control MCU 41 identifies the monitoring target of the battery monitoring device 30 that is the transmission source of the radio signal used for the calculation of the correlation coefficient of 0.7 as the fourth battery block 21D to which the fourth battery monitoring device 30D is mounted.

Next, the battery control MCU 41 calculates correlation coefficients between the strength of the second received signal and the remaining three of the first to fourth reference strengths SLA to SLD. Then, the battery control MCU 41 identifies the battery block 21 that is monitored by the battery monitoring device 30 associated with the reference strength used for the calculation of a maximum correlation coefficient among the three calculated correlation coefficients as the monitoring target of the battery monitoring device 30 that is the transmission source of the radio signal used for the calculation of the maximum correlation coefficient.

Next, the battery control MCU 41 calculates correlation coefficients between the strength of the third received signal and the remaining two of the first to fourth reference strengths SLA to SLD. Then, the battery control MCU 41 identifies the battery block 21 that is monitored by the battery monitoring device 30 associated with the reference strength used for the calculation of a higher correlation coefficient of the two calculated correlation coefficients as the monitoring target of the battery monitoring device 30 that is the transmission source of the radio signal used for the calculation of the higher correlation coefficient. Moreover, the battery control MCU 41 identifies the monitoring target of the battery monitoring device 30 that is the transmission source of the radio signal used for the calculation of a lower correlation coefficient of the two calculated correlation coefficients as the battery block 21 that is monitored by the battery monitoring device 30 associated with the remaining one of the reference strengths.

As the battery blocks 21, which are the monitoring targets of the respective battery monitoring devices 30, are sequentially identified, the number of correlation coefficients to be calculated decreases, thereby reducing the processing load of the battery control MCU 41.

The frequency range of the signal strengths used for the calculation of the correlation coefficients is a frequency range which is defined by at least one channel. Specifically, the frequency range defined by one channel may be, for example, a range from (fc−Δf/2) to (fc+Δf/2); the range is defined by the center frequency fc of the channel and the width Δf of the channel. On the other hand, the frequency range defined by a plurality of channels may be, for example, a range from (fLc−Δf/2) to (fHc+Δf/2); the range is defined by the center frequency fLc of a lowest frequency channel of the plurality of channels, the center frequency fHc of a highest frequency channel of the plurality of channels, and the width Δf of each of the plurality of channels. The wider the frequency range of the signal strengths used for the calculation of the correlation coefficients, the higher the accuracy of identifying the monitoring targets. In contrast, the narrower the frequency range of the signal strengths used for the calculation of the correlation coefficients, the shorter the time required for identifying the monitoring targets.

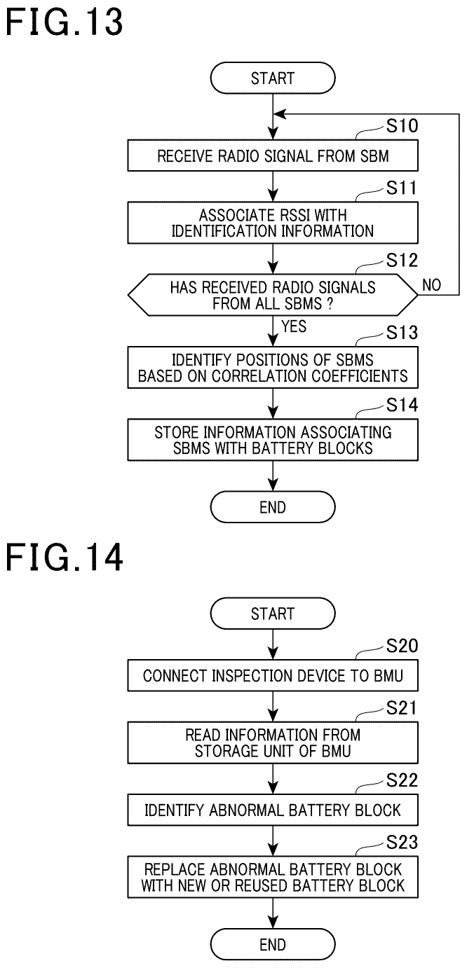

FIG. 13 illustrates the steps of the identification process performed by the battery control MCU 41 in the manufacturing process of the battery pack 11. In addition, the battery control MCU 41 corresponds to an “identification unit”.

In step S10, the battery control MCU 41 receives a radio signal from one battery monitoring device 30 (denoted by SBM in FIG. 13 and the like). The radio signal contains identification information of the battery monitoring device 30 that is the transmission source of the radio signal.

In step S11, the battery control MCU 41 calculates the strength of the received signal (denoted by RSSI (Received Signal Strength Indicator) in FIG. 13 and the like) related to the frequency, and associates the calculated strength with the identification information contained in the received signal.

In step S12, the battery control MCU 41 determines whether it has received radio signals from all of the battery monitoring devices 30A to 30D (denoted by SBMS in FIG. 13 and the like).

If the result of the determination in step S12 is affirmative, the identification process proceeds to step S13. In step S13, the battery control MCU 41 identifies the battery blocks 21, which are monitored respectively by the first to fourth battery monitoring devices 30A to 30D, by the above-described identification method using the correlation coefficients.

In step S14, the battery control MCU 41 stores, in the parent-device-side storage unit 44 of the battery control device 40, information on the correspondence between the first to fourth battery monitoring devices 30A to 30D and the battery blocks 21 that are monitored respectively by the first to fourth battery monitoring devices 30A to 30D. Consequently, it becomes unnecessary to identify the aforementioned correspondence after, for example, the battery pack 11 leaves the manufacturing factory.

As described above, in each of the battery monitoring devices 30, the monitoring IC 31 generates the self-diagnosis information on at least one of the monitoring IC 31 itself and the battery block 21 monitored by the battery monitoring device 30. Then, the monitoring IC 31 transmits the generated self-diagnosis information, together with the identification information, to the battery control device 40. In the case of the diagnosis targets being the battery blocks 21, the battery control device 40 stores, in the parent-device-side storage unit 44, information on that (or those) of the battery blocks 21 in which an abnormality has occurred. The information on the aforementioned correspondence and the information on the abnormal battery block(s) 21, both of which are stored in the parent-device-side storage unit 44, are used during a replacement operation for the abnormal battery block(s) 21 at, for example, a vehicle repair or maintenance shop. Hereinafter, a method of identifying the abnormal battery block(s) 21 will be described with reference to FIG. 14.

In step S20, an operator connects an inspection device at the vehicle repair or maintenance shop to the battery control device 40 (denoted by BMU in FIG. 14 and the like) so that they can communicate with each other. The inspection device may be, for example, a diagnostic tester. In addition, the connection established in this step may be either a wireless connection or a wired connection between the battery control device 40 and the inspection device.

In step S21, the operator operates the inspection device to read, from the parent-device-side storage unit 44 of the battery control device 40, both the information on the correspondence between the first to fourth battery monitoring devices 30A to 30D and the battery blocks 21 that are monitored respectively by the first to fourth battery monitoring devices 30A to 30D and the information on the battery block(s) 21 in which an abnormality has occurred.

In step S22, the inspection device notifies, based on the read information, the operator which of the first to fourth battery blocks 21A to 21D is an abnormal battery block (or are abnormal battery blocks) in which an abnormality has occurred. This notification may be made, for example, by a display on a display unit of the inspection device or by a sound from the inspection device.

In step S23, the operator opens the cover 54 of the housing 50 of the battery pack 11, and removes the battery block(s) 21 in which an abnormality has occurred. Then, the operator installs a new or reused battery block(s) 21 in the housing 50 and closes the cover 54. Consequently, the replacement operation for the abnormal battery block(s) 21 is completed.

It should be noted that after closing the cover 54 of the housing 50, the operator may operate the inspection device to cause the battery control MCU 41 to perform the above-described identification process again. Moreover, in the case of the diagnosis targets in the self-diagnosis information including the battery monitoring devices 30, it is possible to identify the battery monitoring device(s) 30 in which an abnormality has occurred and replace the abnormal battery monitoring device(s) 30 with a normal battery monitoring device(s) 30. In addition, abnormalities which may occur in the battery monitoring devices 30 include abnormalities of the monitoring ICs 31 of the battery monitoring devices 30.

According to the present embodiment described in detail above, although the battery pack 11 includes the accommodation section 55 in which multipath may occur, the battery control device 40 can still ascertain the correspondence between the battery monitoring devices 30 and the battery blocks 21 that are monitored respectively by the battery monitoring devices 30.

Moreover, according to the present embodiment, it becomes possible to identify the battery blocks 21, which are the monitoring targets, without performing special management during the manufacturing process of the battery pack 11.

### [Modifications of First Embodiment]

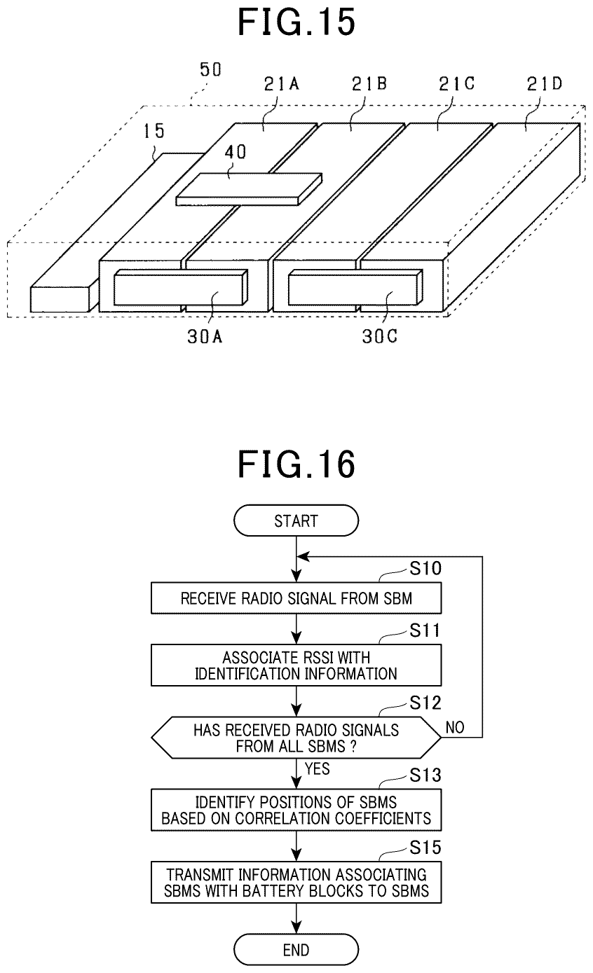

The manner of arranging the battery control device 40 and the battery monitoring devices 30 in the accommodation section 55 of the housing 50 is not limited to that shown in FIGS. 3 and 4. For example, as shown in FIG. 15, the battery control device 40 may alternatively be mounted to upper surfaces of the battery blocks 21; and the battery monitoring devices 30 may alternatively be mounted to side surfaces of the battery blocks 21.

At least one of the bottom plate portion 51, the first wall portions 52, the second wall portions 53 and the cover 54 of the housing 50 may alternatively be configured to have no electromagnetic shielding effect. For example, part of the housing 50 may be formed of a synthetic resin to have no electromagnetic shielding effect.

In the process of identifying the monitoring targets, the first to fourth battery monitoring devices 30A to 30D may transmit radio signals to the battery control device 40 so that the transmission periods of the radio signals at least partially overlap one another. In this case, for each pair of the battery monitoring devices 30 whose radio signal transmission periods overlap each other, it is preferable to set the radio signal transmission frequencies used respectively by the pair of the battery monitoring devices 30 to be considerably different from each other.

The parameters for identifying the battery blocks 21 that are the monitoring targets are not limited to the strengths of the radio signals. For example, as the parameters, communication error rates in the wireless communication between the battery control device 40 and the battery monitoring devices 30 may alternatively be employed. The communication error rates may be, for example, packet error rates or bit error rates. In the case of employing the communication error rates, the parent-device-side storage unit 44 of the battery control device 40 stores therein the communication error rates associated respectively with the battery monitoring devices 30. The battery control device 40 identifies, based on the radio signals received respectively from the battery monitoring devices 30 and the communication error rates stored in the parent-device-side storage unit 44, the battery blocks 21 monitored respectively by the battery monitoring devices 30 that are respectively the transmission sources of the received radio signals.

### Second Embodiment

Hereinafter, a second embodiment will be described with reference to the drawings, focusing on the differences thereof from the first embodiment. In the present embodiment, the information on the correspondence between the first to fourth battery monitoring devices 30A to 30D and the battery blocks 21 that are monitored respectively by the first to fourth battery monitoring devices 30A to 30D is stored in the child-device-side storage unit 34 of each battery monitoring device 30, not in the battery control device 40.

FIG. 16 illustrates the steps of an identification process according to the present embodiment, which is performed by the battery control MCU 41 in the manufacturing process of the battery pack 11. It should be noted that for the sake of convenience, in FIG. 16, steps identical or corresponding to those shown in FIG. 13 are designated by the same reference signs as those shown in FIG. 13.

After completion of step S13, in step S15, the battery control MCU 41 transmits, to the first to fourth battery monitoring devices 30A to 30D, the information on the correspondence between the first to fourth battery monitoring devices 30A to 30D and the battery blocks 21 that are monitored respectively by the first to fourth battery monitoring devices 30A to 30D.

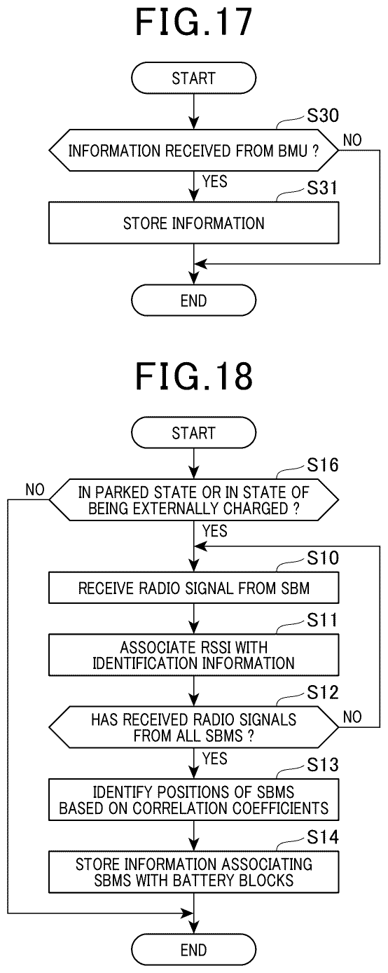

FIG. 17 illustrates the steps of a storage process performed by each of the monitoring ICs 31 of the first to fourth battery monitoring devices 30A to 30D in the manufacturing process of the battery block 11.

In step S30, it is determined whether the information on the aforementioned correspondence has been received from the battery control device 40. If the result of the determination in step S30 is affirmative, the storage process proceeds to step S31. In step S31, the information on the aforementioned correspondence is stored in the child-device-side storage unit 34 of the battery monitoring device 30.

According to the present embodiment described above, it is possible to identify the monitoring targets of the battery monitoring devices 30 (i.e., the child devices) when the battery control device 40 (i.e., the parent device) is in a fault condition. Moreover, it is also possible to reduce the memory usage of the parent-device-side storage unit 44 of the battery control device 40. In addition, in the present embodiment, the information on the reference strengths may be stored alternatively in the child-device-side storage units 34 of the battery monitoring devices 30 by a writing device during the manufacturing process of the battery monitoring devices 30 that are components of the battery pack 11.

### Third Embodiment

Hereinafter, a third embodiment will be described with reference to the drawings, focusing on the differences thereof from the first embodiment. As described above, the identification process is a process of identifying, for each of the battery monitoring devices 30, which of the battery blocks 21 is monitored by the battery monitoring device 30. The identification process can be performed not only during the manufacturing process of the battery pack 11, but also after the vehicle 10 has been delivered to a user. In the present embodiment, the execution of the identification process is permitted when the vehicle 10 is in a parked state or when the assembled battery 20 is in a state of being charged by an external charger CM.

FIG. 18 illustrates the steps of an identification process according to the present embodiment, which is performed by the battery control MCU 41. It should be noted that for the sake of convenience, in FIG. 18, steps identical or corresponding to those shown in FIG. 13 are designated by the same reference signs as those shown in FIG. 13.

In step S16, it is determined whether a first condition or a second condition is satisfied. Here, the first condition is that the vehicle 10 is in a parked state; and the second condition is that the assembled battery 20 installed in the parked vehicle 10 is in a state of being charged by an external charger CM. In addition, step S20 is a step for improving the accuracy of identifying the battery blocks 21 that are monitored respectively by the battery monitoring devices 30.

Due to vibrations and the like that occur during traveling of the vehicle 10, the frequency characteristics of the strengths of the radio signals received by the battery control device 40 may change. In this case, there is a concern that the accuracy of identifying the battery blocks 21 that are the monitoring targets may be lowered or the time required for identifying the battery blocks 21 may be increased. Therefore, it is desirable to perform the identification process in a situation where no vibrations or the like occur. Hence, the first condition is set. In addition, the first condition may be determined to be satisfied when, for example, it is determined that a start switch or an ignition switch is turned off; the start switch or the ignition switch is a switch which is operated by the user to permit traveling of the vehicle 10 or instruct start of the vehicle 10.

When the assembled battery 20 is in a state of being charged by an external charger CM, the vehicle 10 is in a stopped state and thus no vibrations or the like occur. In view of the above, the second condition is set.

According to the present embodiment described above, it is possible to improve the accuracy of identifying the battery blocks 21 that are the monitoring targets of the battery monitoring devices 30.

### Fourth Embodiment

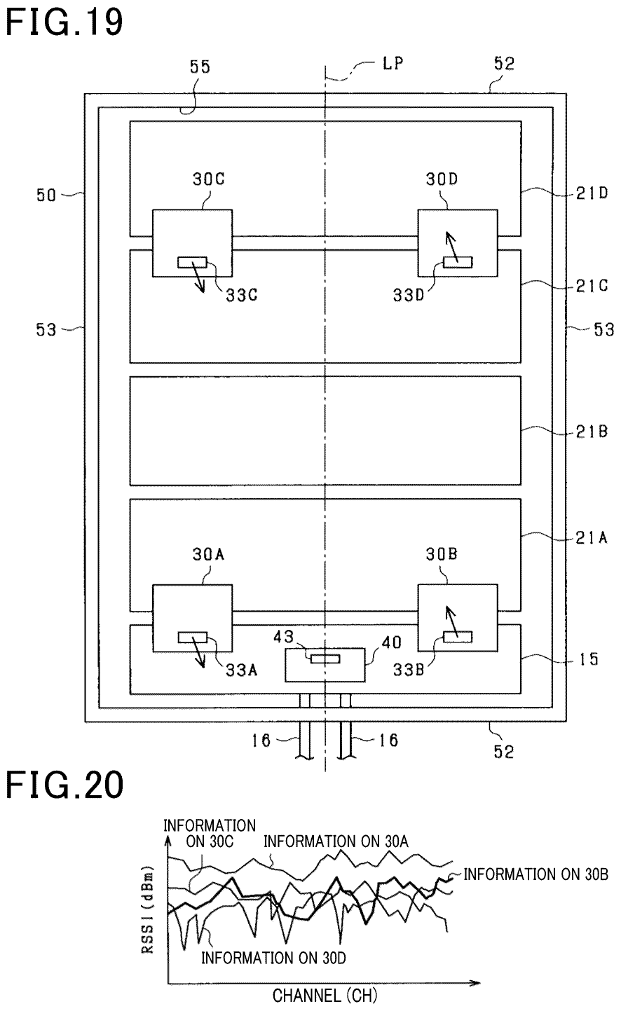

Hereinafter, a fourth embodiment will be described with reference to the drawings, focusing on the differences thereof from the first embodiment. The present embodiment is characterized by the manner of arranging the battery monitoring devices 30 as shown in FIG. 19. FIG. 19 is a plan view of the battery pack 11 according to the present embodiment, wherein the cover 54 of the housing 50 has been removed from the battery pack 11. It should be noted that for the sake of convenience, in FIG. 19, components identical or corresponding to those shown in the previous embodiments are designated by the same reference signs as those shown in the previous embodiments.

In the present embodiment, the battery blocks 21A to 21D, the battery monitoring devices 30A to 30D and the battery control device 40 are arranged in the accommodation section 55 so as to be axisymmetric with respect to a reference axis LP that extends in the longitudinal direction of the housing 50 and a horizontal direction. Moreover, the center of radio wave directivity of the parent-device-side antenna 43 is oriented toward the battery blocks 21, and oriented in the direction in which the reference axis LP extends.

Of the battery monitoring devices 30A to 30D, the first and second battery monitoring devices 30A and 30B are arranged equidistantly from the battery control device 40 (more specifically, from the parent-device-side antenna 43) in the direction in which the reference axis LP extends. Moreover, the centers of radio wave directivity of the first and second child-device-side antennas 33A and 33B of the first and second battery monitoring devices 30A and 30B are oriented so that the orientations of the centers of radio wave directivity are not axisymmetric with respect to the reference axis LP.

Similarly, the third and fourth battery monitoring devices 30C and 30D are also arranged equidistantly from the battery control device 40 in the direction in which the reference axis LP extends. Moreover, the centers of radio wave directivity of the third and fourth child-device-side antennas 33C and 33D of the third and fourth battery monitoring devices 30C and 30D are also oriented so that the orientations of the centers of radio wave directivity are not axisymmetric with respect to the reference axis LP. More particularly, in the present embodiment, the orientations of the centers of radio wave directivity of the first and third child-device-side antennas 33A and 33C are offset by 180 degrees respectively from the orientations of the centers of radio wave directivity of the second and fourth child-device-side antennas 33B and 33D. In addition, the orientations of the centers of radio wave directivity of the first and third child-device-side antennas 33A and 33C are the same; and the orientations of the centers of radio wave directivity of the second and fourth child-device-side antennas 33B and 33D are the same.

With the arrangement shown in FIG. 19, it becomes possible to make the frequency characteristics of the strengths of the radio signals received from the battery monitoring devices 30 by the battery control device 40 considerably different between the first to fourth battery monitoring devices 30A to 30D. As a result, it becomes possible to improve the accuracy of identifying the battery blocks 21 that are the monitoring targets in the identification process.

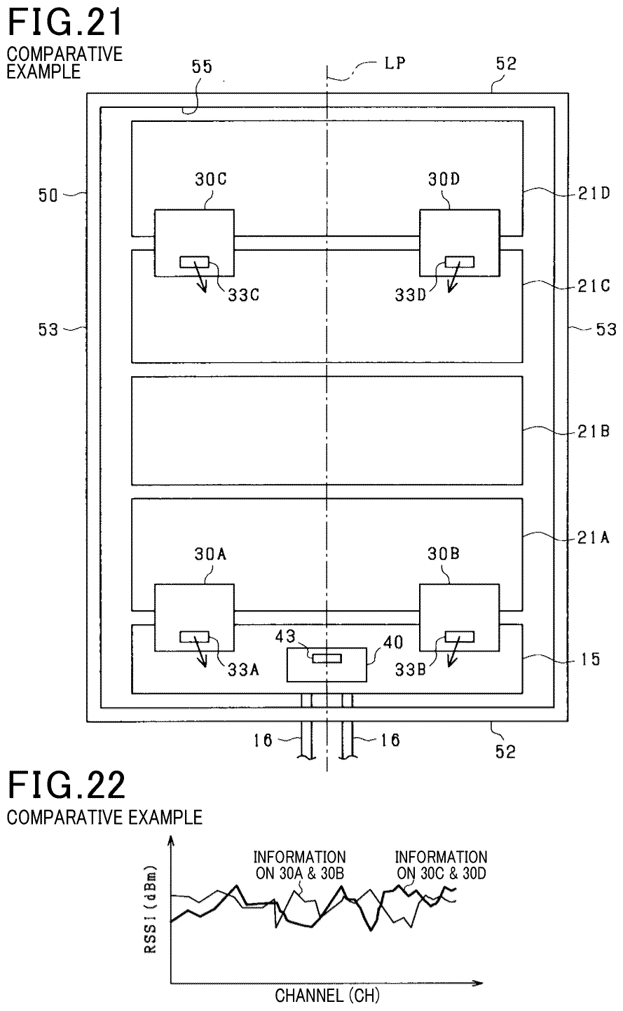

In contrast, in a comparative example shown in FIG. 21, the centers of radio wave directivity of the first and second child-device-side antennas 33A and 33B, which are arranged equidistantly from the battery control device 40 in the direction in which the reference axis LP extends, are oriented so that the orientations of the centers of radio wave directivity are axisymmetric with respect to the reference axis LP. Consequently, as shown in FIG. 22, the frequency characteristics of the strength of the radio signal received from the first battery monitoring device 30A by the battery control device 40 becomes substantially the same as those of the strength of the radio signal received from the second battery monitoring device 30B by the battery control device 40. As a result, it becomes difficult for the battery control device 40 to identify the monitoring targets of the first and second battery monitoring devices 30A and 30B by the identification process.

Moreover, in the comparative example shown in FIG. 21, the centers of radio wave directivity of the third and fourth child-device-side antennas 33C and 33D, which are arranged equidistantly from the battery control device 40 in the direction in which the reference axis LP extends, are also oriented so that the orientations of the centers of radio wave directivity are axisymmetric with respect to the reference axis LP. Consequently, as shown in FIG. 22, the frequency characteristics of the strength of the radio signal received from the third battery monitoring device 30C by the battery control device 40 becomes substantially the same as those of the strength of the radio signal received from the fourth battery monitoring device 30D by the battery control device 40. As a result, it becomes difficult for the battery control device 40 to identify the monitoring targets of the third and fourth battery monitoring devices 30C and 30D by the identification process.

### Fifth Embodiment

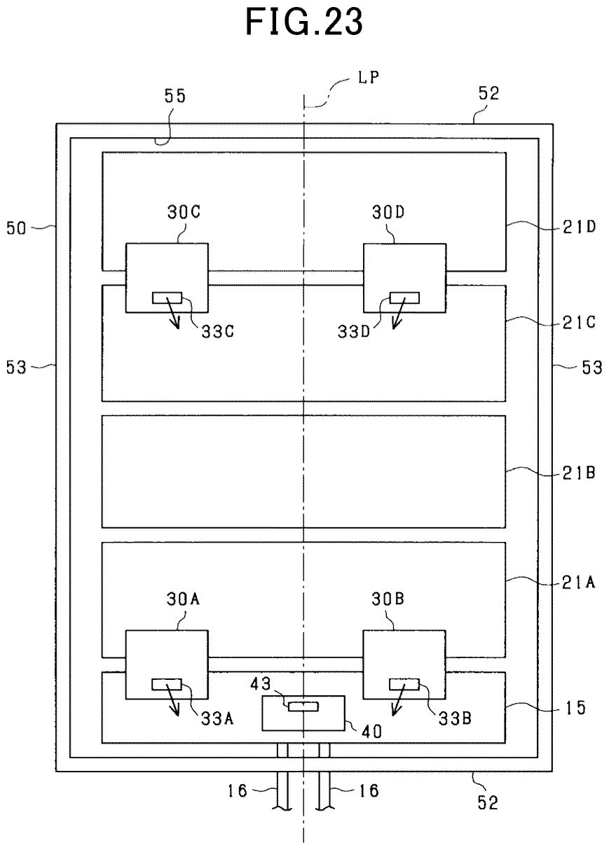

Hereinafter, a fifth embodiment will be described with reference to the drawings, focusing on the differences thereof from the fourth embodiment. In the present embodiment, as shown in FIG. 23, the first and second battery monitoring devices 30A and 30B, which are arranged equidistantly from the battery control device 40 in the direction in which the reference axis LP extends (i.e., in the longitudinal direction of the housing 50), are arranged at different distances from the reference axis LP in the lateral direction of the housing 50. Similarly, the third and fourth battery monitoring devices 30C and 30D, which are arranged equidistantly from the battery control device 40 in the direction in which the reference axis LP extends, are arranged at different distances from the reference axis LP in the lateral direction of the housing 50. It should be noted that for the sake of convenience, in FIG. 23, components identical or corresponding to those shown in FIG. 19 are designated by the same reference signs as those shown in FIG. 19.

Moreover, in the present embodiment, the centers of radio wave directivity of the first and second child-device-side antennas 33A and 33B of the first and second battery monitoring devices 30A and 30B are oriented so that the orientations of the centers of radio wave directivity are axisymmetric with respect to the reference axis LP. However, even in this case, with the distances from the reference axis LP in the lateral direction of the housing 50 different between the first and second battery monitoring devices 30A and 30B, it still becomes possible to make the frequency characteristics of the strengths of the radio signals received from the battery monitoring devices 30 by the battery control device 40 considerably different between the first and second battery monitoring devices 30A and 30B. Similarly, the centers of radio wave directivity of the third and fourth child-device-side antennas 33C and 33D of the third and fourth battery monitoring devices 30C and 30D are also oriented so that the orientations of the centers of radio wave directivity are axisymmetric with respect to the reference axis LP. However, even in this case, with the distances from the reference axis LP in the lateral direction of the housing 50 different between the third and fourth battery monitoring devices 30C and 30D, it still becomes possible to make the frequency characteristics of the strengths of the radio signals received from the battery monitoring devices 30 by the battery control device 40 considerably different between the third and fourth battery monitoring devices 30C and 30D.

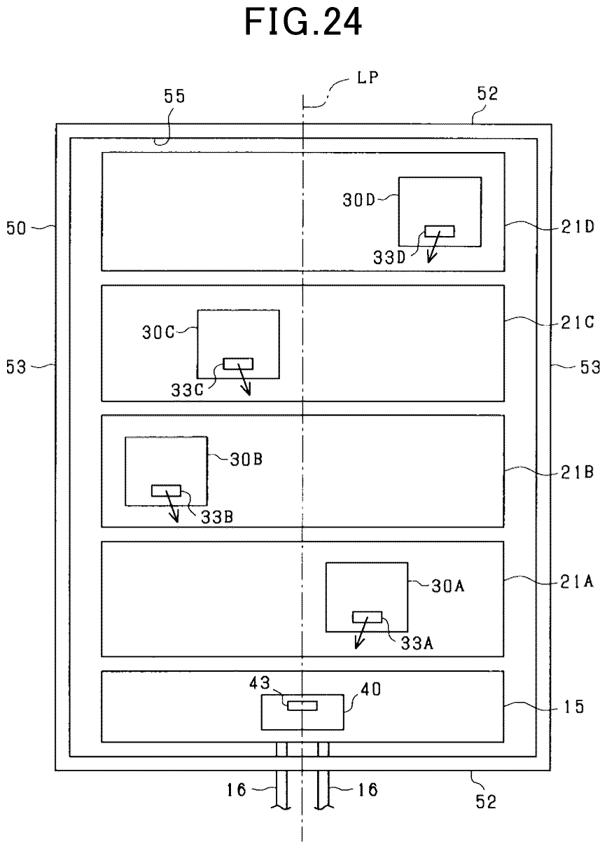

The manner of arranging the battery monitoring devices 30A to 30D and the child-device-side antennas 33A to 33D is not limited to that shown in FIG. 23. For example, the battery monitoring devices 30A to 30D and the child-device-side antennas 33A to 33D may alternatively be arranged as shown in FIG. 24. Specifically, in the example shown in FIG. 24, all the distances from the reference axis LP to the battery monitoring devices 30A to 30D in the lateral direction of the housing 50 are different from each other. In addition, in the example shown in FIG. 24, the battery control device 40 is arranged at a central position in the lateral direction of the housing 50; alternatively, the battery control device 40 may be arranged at either a right end position or a left end position in the lateral direction of the housing 50.

### Sixth Embodiment

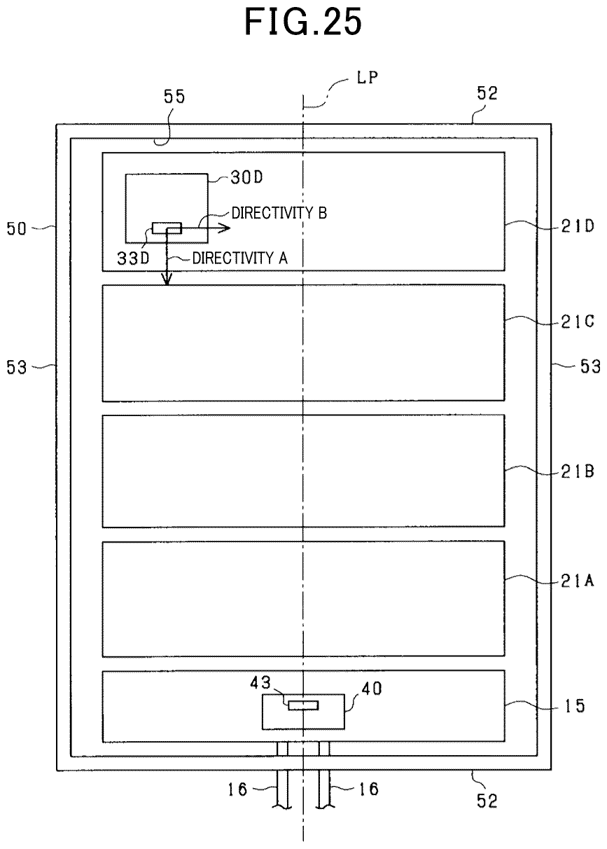

Hereinafter, a sixth embodiment will be described with reference to the drawings, focusing on the differences thereof from the first embodiment. In the present embodiment, each of the child-device-side antennas 33A to 33D is configured so that the orientation of the center of radio wave directivity thereof can be selected from a plurality of orientations and changed (or set) to the selected orientation. It should be noted that for the sake of simplicity, in FIG. 25, there is shown only the fourth battery monitoring device 30D among the first to fourth battery monitoring devices 30A to 30D.

The fourth child-device-side antenna 33D is configured so that the orientation of the center of radio wave directivity can be selected from two orientations and changed (or set) to the selected orientation. Specifically, when directivity A is selected, the center of the radio wave directivity of the fourth child-device-side antenna 33D is oriented in the longitudinal direction of the housing 50. In contrast, when directivity B is selected, the center of the radio wave directivity of the fourth child-device-side antenna 33D is oriented in the lateral direction of the housing 50.

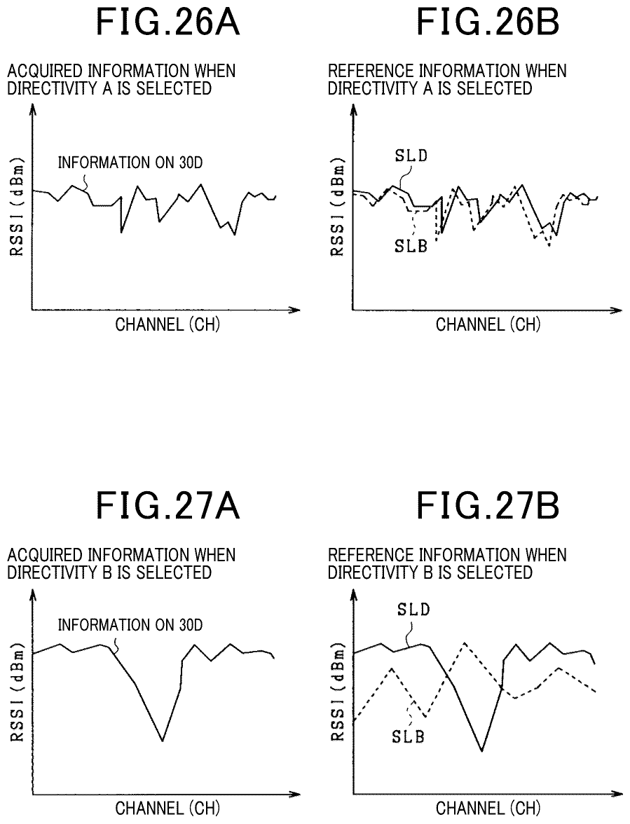

The above configuration that allows the orientation of the center of radio wave directivity to be changed is employed for improving the accuracy of identifying the monitoring target. Specifically, FIG. 26A illustrates the frequency characteristics of the strength of the radio signal received from the fourth battery monitoring device 30D by the battery control device 40 when directivity A is selected. On the other hand, FIG. 26B illustrates the frequency characteristics of the second and fourth reference strengths SLB and SLD associated respectively with the second and fourth battery monitoring devices 30B and 30D when directivity A is selected. In this case (i.e., when directivity A is selected), it is difficult to identify, based on the strength of the radio signal shown in FIG. 26A, whether the monitoring target is the second battery block 21B to which the second battery monitoring device 30B is mounted or the fourth battery block 21D to which the fourth battery monitoring device 30D is mounted.

To solve the above problem, the directivity can be switched to from A to B. FIG. 27A illustrates the frequency characteristics of the strength of the radio signal received from the fourth battery monitoring device 30D by the battery control device 40 when directivity B is selected. On the other hand, FIG. 27B illustrates the frequency characteristics of the second and fourth reference strengths SLB and SLD associated respectively with the second and fourth battery monitoring devices 30B and 30D when directivity B is selected. In this case (i.e., when directivity B is selected), it is possible to easily identify, based on the strength of the radio signal shown in FIG. 27A, the monitoring target as the fourth battery block 21D to which the fourth battery monitoring device 30D is mounted.

In the present embodiment, in the parent-device-side storage unit 44, there are stored both the first to fourth reference strengths SLA to SLD associated with directivity A and the first to fourth reference strengths SLA to SLD associated with directivity B. In the identification process, when, for example, the difference between the maximum (or highest) correlation coefficient and the second highest correlation coefficient is less than or equal to a predetermined value, the battery control MCU 41 may switch the directivity from A to B and identify the monitoring target with directivity B.

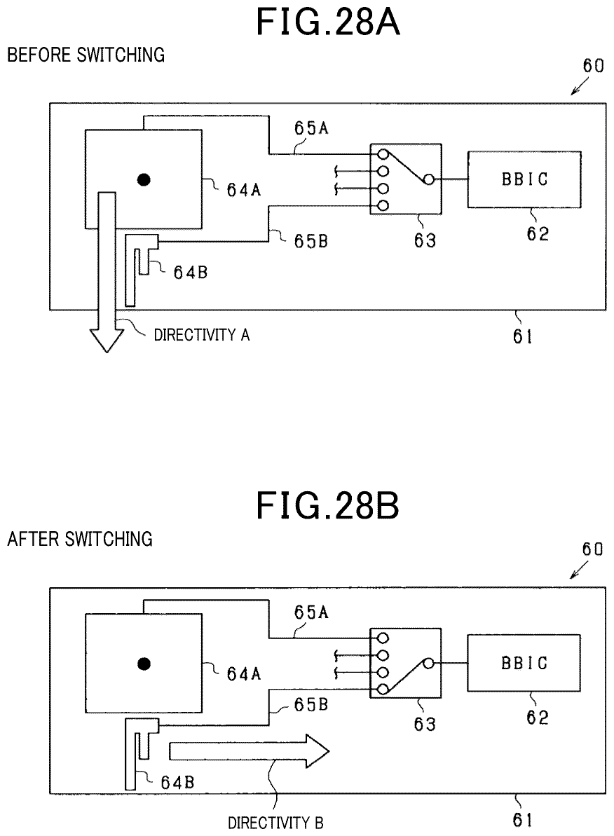

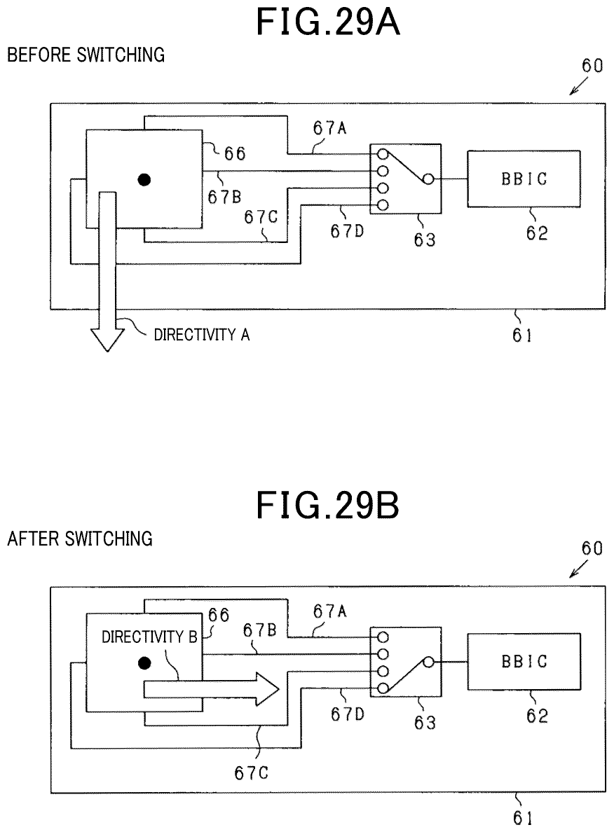

Hereinafter, two examples of a child-device-side antenna capable of changing the orientation of the center of radio wave directivity will be described with reference to FIGS. 28A-28B and FIGS. 29A-29B.

FIGS. 28A and 28B illustrate a first example of a child-device-side antenna 60. In the first example, the child-device-side antenna 60 includes a plurality of antennas having different orientations of centers of radio wave directivity and is configured to switch the antenna to be used between the plurality of antennas.

Specifically, in the first example, the child-device-side antenna 60 includes a circuit board 61. Moreover, on a surface of the circuit board 61, there are provided a baseband IC 62, a changeover switch 63, the plurality of antennas, a first power supply line 65A and a second power supply line 65B. In addition, in FIGS. 28A and 28B, there are shown a first antenna 64A and a second antenna 64B as the plurality of antennas.

The baseband IC 62 communicates with the monitoring IC 31 via the child-device-side wireless IC 32. The baseband IC 62 is connected to either the first power supply line 65A or the second power supply line 65B by the changeover switch 63. As shown in FIG. 28A, when the baseband IC 62 and the first power supply line 65A are connected by the changeover switch 63, the first antenna 64A is used. In this case, the radio wave directivity of the child-device-side antenna 60 is directivity A. On the other hand, as shown in FIG. 28B, when the baseband IC 62 and the second power supply line 65B are connected by the changeover switch 63, the second antenna 64B is used. In this case, the radio wave directivity of the child-device-side antenna 60 is directivity B.

FIGS. 29A and 29B illustrate a second example of a child-device-side antenna 60. In the second example, the radio wave directivity of the child-device-side antenna 60 is changed by changing the power supply line to be used. It should be noted that for the sake of convenience, in FIGS. 29A and 29B, components identical or corresponding to those shown in FIGS. 28A and 28B are designated by the same reference signs as those shown in FIGS. 28A and 28B.

Specifically, in the second example, the child-device-side antenna 60 includes an antenna 66 and first to fourth power supply lines 67A to 67D. The antenna 66 and the first to fourth power supply lines 67A to 67D are provided on a surface of a circuit board 61. The antenna 66 may be for example, a patch antenna.

In the second example shown in FIGS. 29A and 29B, the radio wave directivity of the antenna 66 can be switched between four directivities, only two of which will be explained below. As shown in FIG. 29A, when the baseband IC 62 and the first power supply line 67A are connected by a changeover switch 63, the radio wave directivity of the antenna 66 is directivity A. On the other hand, as shown in FIG. 29B, when the baseband IC 62 and the fourth power supply line 67D are connected by the changeover switch 63, the radio wave directivity of the antenna 66 is directivity B.

It should be noted that: instead of employing the changeover switch 63, the child-device-side antenna 60 may employ a plurality of baseband ICs 62 that are connected respectively to the plurality of power supply lines; and the radio wave directivity of the antenna 66 may be changed by switching the baseband IC 62 to be operated between the plurality of baseband ICs 62.

According to the present embodiment described above, it is possible to improve the accuracy of identifying the battery blocks 21 that are the monitoring targets of the battery monitoring devices 30.

### [Modification of Sixth Embodiment]

Instead of or in addition to the child-device-side antennas 33, the parent-device-side antenna 43 of the battery control device 40 may be configured so that the radio wave directivity thereof can be changed.

### Seventh Embodiment

Hereinafter, a seventh embodiment will be described with reference to the drawings, focusing on the differences thereof from the first embodiment. In the first embodiment, correlation coefficients are used to identify the battery blocks 21 that are monitored respectively by the battery monitoring devices 30. In contrast, in the present embodiment, correlation coefficients are used to determine whether an abnormality has occurred in the battery pack 11.

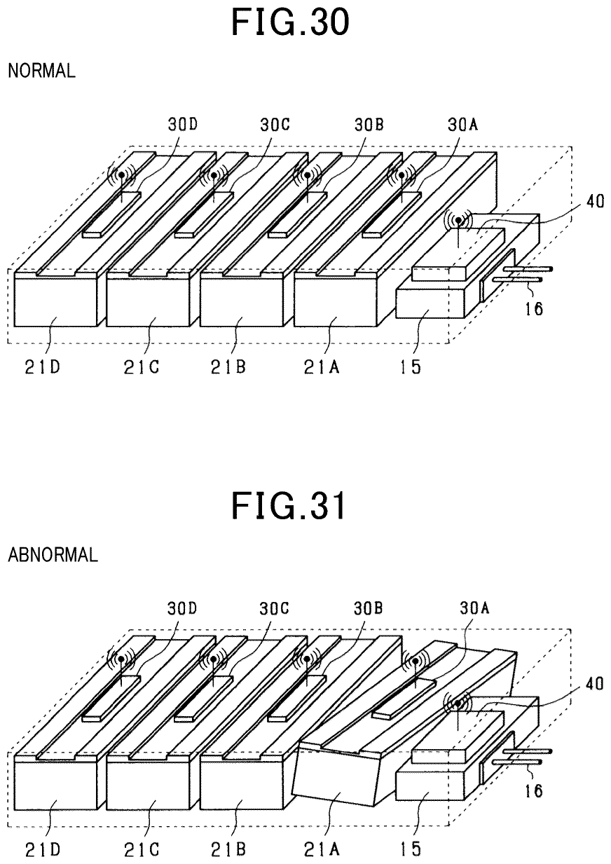

FIG. 30 illustrates a battery pack 11 in a normal state, whereas FIG. 31 illustrates a battery pack 11 in an abnormal state. Moreover, in FIGS. 30 and 31, there are also shown busbars that electrically connect positive-electrode and negative-electrode terminals of adjacent battery cells 22 in each of the battery blocks 21. It should be noted that for the sake of convenience, in FIGS. 30 and 31, components identical or corresponding to those shown in FIGS. 3 and 4 are designated by the same reference signs as those shown in FIGS. 3 and 4.

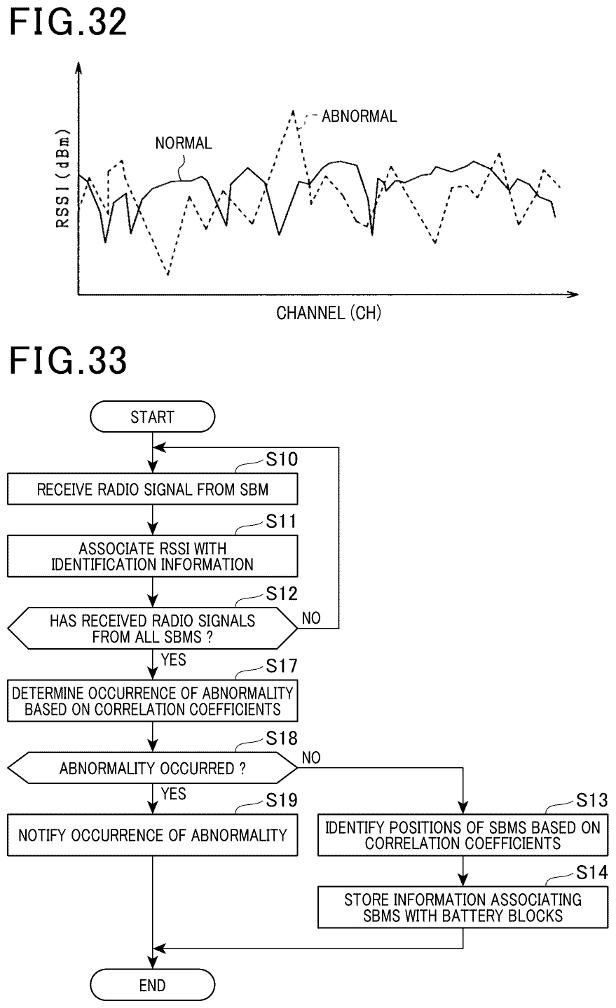

In the example illustrated in FIG. 31, the arrangement position of the first battery block 21A is deviated from the normal arrangement position thereof. Consequently, as shown in FIG. 32, the strength of the radio signal received from the first battery monitoring device 30A by the battery control device 40 is considerably deviated from the normal strength. Based on this deviation, it is possible to determine whether an abnormality has occurred in the battery pack 11. In addition, abnormalities of the battery pack 11 other than that illustrated in FIG. 31 may include, for example, deviation of the arrangement positions of the battery monitoring devices 30 from the normal arrangement positions thereof and detachment of the cover 54 from the housing 50.

FIG. 33 illustrates the steps of an identification process according to the present embodiment, which is performed by the battery control MCU 41. It should be noted that for the sake of convenience, in FIG. 33, steps identical or corresponding to those shown in FIG. 13 are designated by the same reference signs as those shown in FIG. 13.

In the present embodiment, if the result of the determination in step S12 is affirmative, the identification process proceeds to step S17. In step S17, the battery control MCU 41 calculates correlation coefficients by the same method as that used in step S13 and described in the first embodiment. Then, based on the calculated correlation coefficients, the battery control MCU 41 determines whether an abnormality has occurred in the battery pack 11. For example, the battery control MCU 41 may calculate, for each received radio signal, the correlation coefficients between the strength of the received radio signal and the first to fourth reference strengths SLA to SLD. Further, if all the four calculated correlation coefficients are lower than or equal to a threshold value, the battery control MCU 41 may determine that an abnormality has occurred in the battery pack 11. In addition, the threshold value may be set to a value (e.g., 0.4) indicating a weak correlation or a value (e.g., 0.2) indicating almost zero correlation.

In step S18, it is determined whether an abnormality has occurred in the battery pack 11. If the result of the determination in step S18 is negative, the identification process proceeds to step S13. In contrast, if the result of the determination in step S18 is affirmative, the identification process proceeds to step S19. In step S19, the battery control MCU 41 performs a process of notifying the user that an abnormality has occurred in the battery pack 11.

According to the present embodiment described above, it is possible to determine whether an abnormality has occurred in the battery pack 11.

### Eighth Embodiment

Hereinafter, an eighth embodiment will be described with reference to the drawings, focusing on the differences thereof from the first embodiment. In the present embodiment, the battery blocks 21, which are monitored respectively by the battery monitoring devices 30A to 30D, are identified by comparing the magnitude relationship between the strengths of the radio signals received from the battery monitoring devices 30A to 30D at a specific frequency with the magnitude relationship between the first to fourth reference strengths SLA to SLD at the specific frequency, instead of using the correlation coefficients.

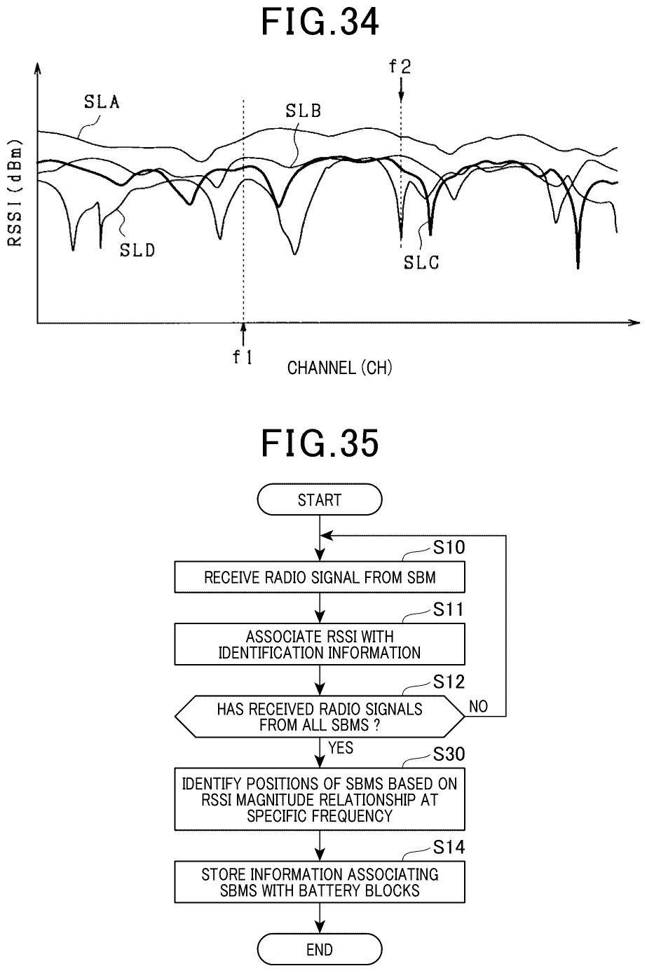

Referring to FIG. 34, explanation will be given of an identification process according to the present embodiment, with the specific frequency being f1. For example, assume that at the specific frequency f1, the first reference strength SLA is −10 dBm; the second reference strength SLB is −20 dBm; the third reference strength SLC is −30 dBm; and the fourth reference strength SLD is −40 dBm. All the reference strengths SLA to SLD at the specific frequency f1 are stored in the parent-device-side storage unit 44 of the battery control device 40.

The battery control MCU 41 acquires the strengths of the four radio signals received respectively from the battery monitoring devices 30A to 30D. For example, assume that the strength of the radio signal received from the first battery monitoring device 30A is −22 dBm; the strength of the radio signal received from the second battery monitoring device 30B is −28 dBm; the strength of the radio signal received from the third battery monitoring device 30C is −38 dBm; and the strength of the radio signal received from the fourth battery monitoring device 30D is −55 dBm.

The magnitude relationship between the reference strengths is (SLA>SLB>SLC>SLD). On the other hand, the magnitude relationship between the acquired strengths is (strength of 30A>strength of 30B>strength of 30C>strength of 30D). The battery control MCU 41 identifies the battery blocks 21 monitored respectively by the battery monitoring devices 30 so that the magnitude relationship between the reference strengths and the magnitude relationship between the acquired strengths coincide with each other. Specifically, the battery control MCU 41 identifies the monitoring target of the first battery monitoring device 30A as the first battery block 21A associated with the first reference strength SLA, and identifies the monitoring target of the second battery monitoring device 30B as the second battery block 21B associated with the second reference strength SLB. Moreover, the battery control MCU 41 identifies the monitoring target of the third battery monitoring device 30C as the third battery block 21C associated with the third reference strength SLC, and identifies the monitoring target of the fourth battery monitoring device 30D as the fourth battery block 21D associated with the fourth reference strength SLD.

Although f1 is exemplified above as the specific frequency, f2 that is, for example, higher than f1 may alternatively be employed as the specific frequency. Moreover, the specific frequency is not limited to a predetermined fixed frequency, but may be a frequency selected based on the frequency characteristics of the strengths of the radio signals calculated by the battery control device 40.

FIG. 35 illustrates the steps of an identification process according to the present embodiment, which is performed by the battery control MCU 41 in the manufacturing process of the battery pack 11. It should be noted that for the sake of convenience, in FIG. 35, steps identical or corresponding to those shown in FIG. 13 are designated by the same reference signs as those shown in FIG. 13.

In the present embodiment, if the result of the determination in step S12 is affirmative, the identification process proceeds to step S30. In step S30, the battery control MCU 41 identifies the battery blocks 21, which are monitored respectively by the first to fourth battery monitoring devices 30A to 30D, by the above-described identification method using the magnitude relationships.

According to the present embodiment described above, the number of frequencies required for the identification of the monitoring targets of the battery monitoring devices 30 (i.e., the battery blocks 21) can be reduced; thus, the time required for the identification of the monitoring targets can be shortened.

### Ninth Embodiment

Hereinafter, a ninth embodiment will be described with reference to the drawings, focusing on the differences thereof from the eighth embodiment. In the present embodiment, the battery blocks 21, which are monitored respectively by the battery monitoring devices 30A to 30D, are identified based on the differences at a specific frequency between the strengths of the radio signals received from the battery monitoring devices 30A to 30D and the reference strengths.

Referring back to FIG. 34, explanation will be given of an identification process according to the present embodiment, with the specific frequency being f1.

For example, assume that at the specific frequency f1, the first reference strength SLA is −10 dBm; the second reference strength SLB is −20 dBm; the third reference strength SLC is −30 dBm; and the fourth reference strength SLD is −40 dBm. All the reference strengths SLA to SLD at the specific frequency f1 are stored in the parent-device-side storage unit 44 of the battery control device 40.

The battery control MCU 41 calculates the differences between the strength of the received signal from a first one of the battery monitoring devices 30 at the specific frequency and the first to fourth reference strengths SLA to SLD at the specific frequency. Here, assume that the strength of the received signal at the specific frequency is −22 dBm. Accordingly, at the specific frequency, the difference of the strength of the received signal from the first reference strength SLA is 12 dBm; that from the second reference strength SLB is 2 dBm; that from the third reference strength SLC is 8 dBm; and that from the fourth reference strength SLD is 18 dBm.

The battery control MCU 41 identifies the second battery block 21B, which is the monitoring target of the second battery monitoring device 30B associated with the second reference strength SLB used for the calculation of a minimum difference among the four calculated differences, as the monitoring target of the battery monitoring device 30 that is the transmission source of the radio signal used for the calculation of the minimum difference. In addition, when two of the four calculated differences are equal to each other, the battery control MCU 41 may preferentially identify the monitoring target of a second one of the battery monitoring devices 30 based on the received signal from the second one of the battery monitoring devices 30.

Further, using the same method as described above, the battery control MCU 41 sequentially identifies the battery blocks 21, which are monitored respectively by the remaining battery monitoring devices 30, based on the remaining received signals.

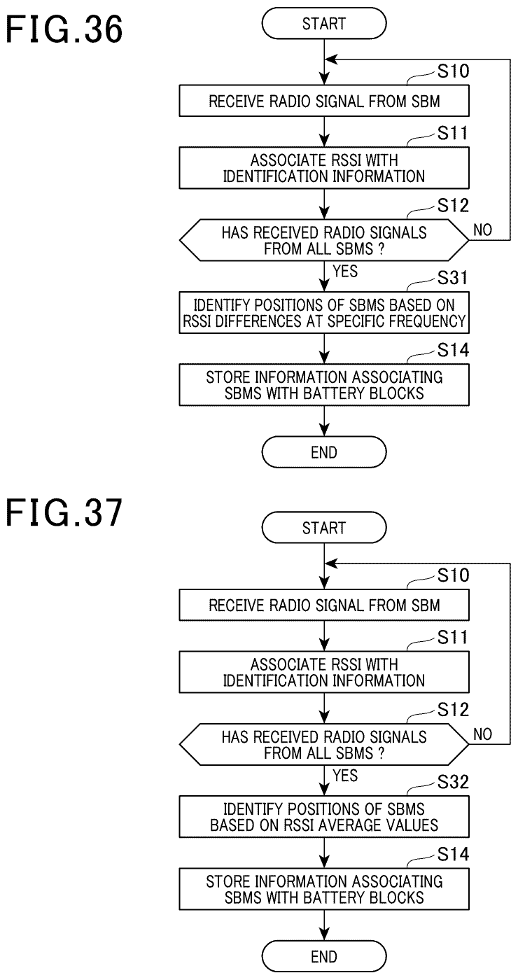

FIG. 36 illustrates the steps of an identification process according to the present embodiment, which is performed by the battery control MCU 41 in the manufacturing process of the battery pack 11. It should be noted that for the sake of convenience, in FIG. 36, steps identical or corresponding to those shown in FIG. 35 are designated by the same reference signs as those shown in FIG. 35.

In the present embodiment, if the result of the determination in step S12 is affirmative, the identification process proceeds to step S31. In step S31, the battery control MCU 41 identifies the battery blocks 21, which are monitored respectively by the first to fourth battery monitoring devices 30A to 30D, by the above-described identification method using the differences.

According to the present embodiment described above, the number of frequencies required for the identification of the monitoring targets of the battery monitoring devices 30 (i.e., the battery blocks 21) can be reduced; thus, the time required for the identification of the monitoring targets can be shortened.

In addition, the accuracy of identifying the monitoring targets can be further improved by combining the identification method according to the present embodiment with the identification method according to the eighth embodiment.

### Tenth Embodiment

Hereinafter, a tenth embodiment will be described with reference to the drawings, focusing on the differences thereof from the eighth and ninth embodiments. In the present embodiment, the battery blocks 21, which are monitored respectively by the battery monitoring devices 30A to 30D, are identified based on the average values of the strengths of the radio signals received from the battery monitoring devices 30A to 30D in a predetermined frequency range and the average values of the first to fourth reference strengths SLA to SLD in the predetermined frequency range. It is preferable that the predetermined frequency range is a frequency range in which the first to fourth reference strengths SLA to SLD considerably differ from each other. In addition, the average values of the first to fourth reference strengths SLA to SLD in the predetermined frequency range are stored in the parent-device-side storage unit 44 of the battery control device 40.

The battery control MCU 41 calculates the average value of the strength of the received signal from a first one of the battery monitoring devices 30 in the predetermined frequency range. Further, the battery control MCU 41 calculates the differences between the calculated average value and the average values of the first to fourth reference strengths SLA to SLD in the predetermined frequency range.

The battery control MCU 41 identifies the battery block 21 that is monitored by the battery monitoring device 30 associated with the reference strength used for the calculation of a minimum difference among the four calculated differences as the monitoring target of the battery monitoring device 30 that is the transmission source of the radio signal used for the calculation of the average value in the predetermined frequency range. Further, using the same method as described above, the battery control MCU 41 sequentially identifies the battery blocks 21, which are monitored respectively by the remaining battery monitoring devices 30, based on the remaining received signals.

FIG. 37 illustrates the steps of an identification process according to the present embodiment, which is performed by the battery control MCU 41 in the manufacturing process of the battery pack 11. It should be noted that for the sake of convenience, in FIG. 37, steps identical or corresponding to those shown in FIG. 35 are designated by the same reference signs as those shown in FIG. 35.

In the present embodiment, if the result of the determination in step S12 is affirmative, the identification process proceeds to step S32. In step S32, the battery control MCU 41 identifies the battery blocks 21, which are monitored respectively by the first to fourth battery monitoring devices 30A to 30D, by the above-described identification method using the differences between the average values.

### Eleventh Embodiment

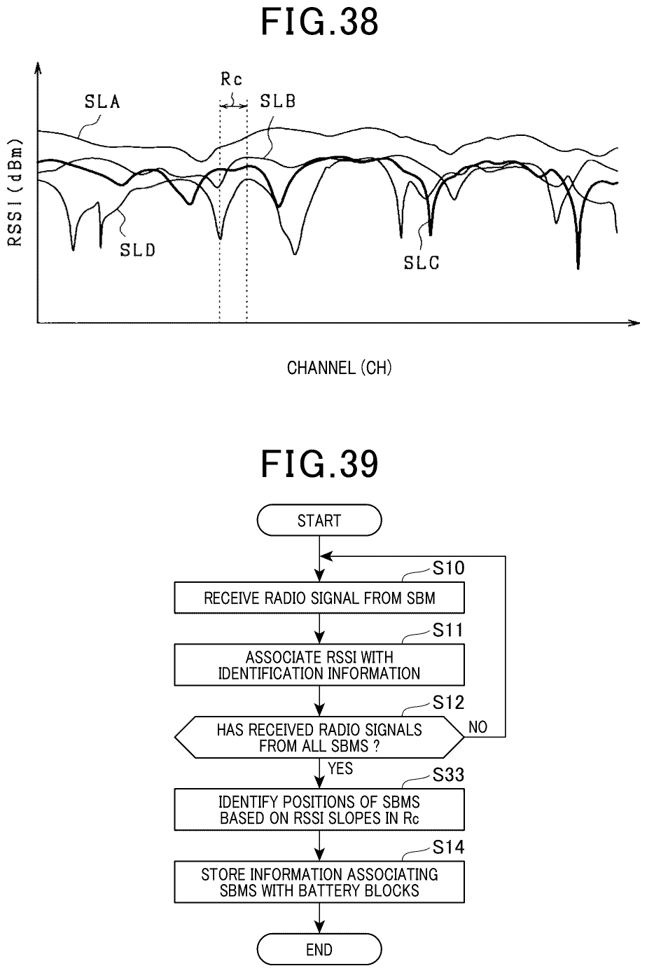

Hereinafter, an eleventh embodiment will be described with reference to the drawings, focusing on the differences thereof from the first embodiment. In the present embodiment, the battery blocks 21, which are monitored respectively by the battery monitoring devices 30A to 30D, are identified based on the slopes of the strengths of the radio signals received from the battery monitoring devices 30A to 30D in a predetermined frequency range Rc and the slopes of the first to fourth reference strengths SLA to SLD in the predetermined frequency range Rc. It is preferable that the predetermined frequency range Rc is a frequency range in which the slopes of the first to fourth reference strengths SLA to SLD considerably differ from each other, as shown in FIG. 38. In addition, the slopes of the first to fourth reference strengths SLA to SLD in the predetermined frequency range Rc are stored in the parent-device-side storage unit 44 of the battery control device 40.

The battery control MCU 41 calculates the slope of the strength of the received signal from a first one of the battery monitoring devices 30 in the predetermined frequency range Rc. Further, the battery control MCU 41 calculates the differences between the calculated slope and the slopes of the first to fourth reference strengths SLA to SLD in the predetermined frequency range Rc.

The battery control MCU 41 identifies the battery block 21 that is monitored by the battery monitoring device 30 associated with the reference strength used for the calculation of a minimum difference among the four calculated differences as the monitoring target of the battery monitoring device 30 that is the transmission source of the radio signal used for the calculation of the slope in the predetermined frequency range Rc. Further, using the same method as described above, the battery control MCU 41 sequentially identifies the battery blocks 21, which are monitored respectively by the remaining battery monitoring devices 30, based on the remaining received signals.

FIG. 39 illustrates the steps of an identification process according to the present embodiment, which is performed by the battery control MCU 41 in the manufacturing process of the battery pack 11. It should be noted that for the sake of convenience, in FIG. 39, steps identical or corresponding to those shown in FIG. 35 are designated by the same reference signs as those shown in FIG. 35.

In the present embodiment, if the result of the determination in step S12 is affirmative, the identification process proceeds to step S33. In step S33, the battery control MCU 41 identifies the battery blocks 21, which are monitored respectively by the first to fourth battery monitoring devices 30A to 30D, by the above-described identification method using the differences between the slopes.

According to the present embodiment described above, it is possible to identify the monitoring targets of the battery monitoring devices 30 (i.e., the battery blocks 21) even when, for example, the strengths of the received radio signals do not match the reference strengths.

### Twelfth Embodiment

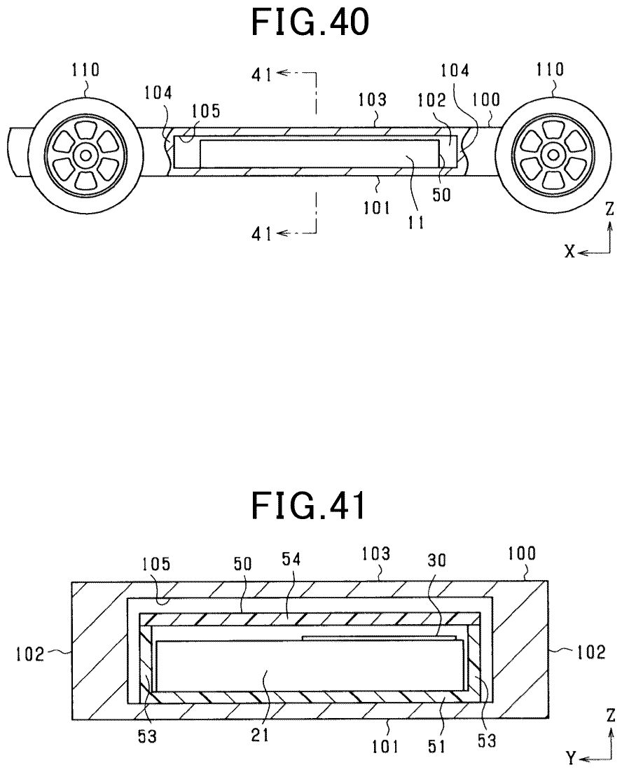

Hereinafter, a twelfth embodiment will be described with reference to FIGS. 40 and 41, focusing on the differences thereof from the previous embodiments. It should be noted that for the sake of convenience, in FIGS. 40 and 41, components identical or corresponding to those described in the previous embodiments are designated by the same reference signs as those described in the previous embodiments. In addition, FIG. 41 is a cross-sectional view taken along the line 41-41 in FIG. 40.

In the present embodiment, the vehicle 10 includes a chassis 100 formed of a metal material as a body of the vehicle 10, and wheels 110. The chassis 100 includes a chassis bottom plate portion 101 extending in the longitudinal direction of the vehicle 10, side plate portions 102, a chassis top plate portion 103, and end plate portions 104. The side plate portions 102 extend upward respectively from opposite end portions of the chassis bottom plate portion 101 in the lateral direction of the vehicle 10. The chassis top plate portion 103 covers the side plate portions 102 from above. The end plate portions 104 respectively cover opposite end portions of the chassis bottom plate portion 101 in the longitudinal direction of the vehicle 10, opposite end portions of each of the side plate portions 102 in the longitudinal direction of the vehicle 10, and opposite end portions of the chassis top plate portion 103 in the longitudinal direction of the vehicle 10. Consequently, an accommodation section 105 is formed by interior surfaces of the chassis bottom plate portion 101, the side plate portions 102, the chassis top plate portion 103 and the end plate portions 104. The battery pack 11 is accommodated in the accommodation section 105.

Specifically, the bottom plate portion 51 of the housing 50 is arranged on the chassis bottom plate portion 101. On the other hand, a gap is formed between the chassis top plate portion 103 and the cover 54 of the housing 50. In the present embodiment, all of the bottom plate portion 51, the first wall portions 52, the second wall portions 53 and the cover 54 of the housing 50 are formed of a synthetic resin to have no electromagnetic shielding effect. Therefore, radio waves transmitted from the parent-device-side antenna 43 or the child-device-side antennas 33 pass through the housing 50. However, the radio waves are reflected by the chassis 100 that is formed of a metal material.

It should be noted that a configuration may alternatively be employed where only some of the bottom plate portion 51, the first wall portions 52, the second wall portions 53 and the cover 54 of the housing 50 (e.g., only the cover 54) are formed of a synthetic resin to have no electromagnetic shielding effect.

In the present embodiment described above, diffuse reflection of radio waves occurs in the accommodation section 105. Therefore, the configurations of the battery monitoring systems described in the previous embodiments can also be applied to the present embodiment.

### Thirteenth Embodiment

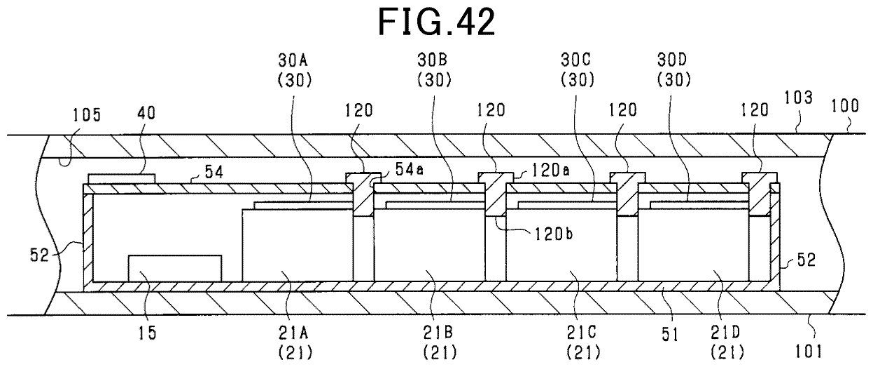

Hereinafter, a thirteenth embodiment will be described with reference to FIG. 42, focusing on the differences thereof from the twelfth embodiment. It should be noted that for the sake of convenience, in FIG. 42, components identical or corresponding to those described in the previous embodiments are designated by the same reference signs as those described in the previous embodiments.

In the present embodiment, the battery control device 40 is located in the accommodation section 105 and outside the housing 50. More specifically, the battery control device 40 is mounted to an upper surface of the cover 54.

Moreover, in the present embodiment, all of the bottom plate portion 51, the first wall portions 52, the second wall portions 53 and the cover 54 of the housing 50 are formed of a metal material. Therefore, in order to enable communication between the battery monitoring devices 30A to 30D accommodated in the housing 50 and the battery control device 40 located outside the housing 50, it is required to communicably connect the inside and outside of the housing 50.

To meet the above requirement, in the present embodiment, the battery pack 11 includes relay devices 120. Each of the relay devices 120 has an antenna 120a located on the upper surface of the cover 54, and a shaft portion 120b extending downward from the antenna 120a and having a smaller outer diameter than the antenna 120a. In the cover 54, there are formed through-holes 54a through which the shaft portions 120b of the relay devices 120 are respectively inserted into the housing 50. More particularly, in the present embodiment, the through-holes 54a are formed in the cover 54 so as to be aligned in a row in a longitudinal direction of the cover 54. Each of the relay devices 120 is arranged to have the antenna 120a thereof located on the upper surface of the cover 54 and the shaft portion 120b thereof inserted into the housing 50 through a corresponding of the through-holes 54a formed in the cover 54. Moreover, the relay devices 120 are provided individually to respectively correspond to the battery monitoring devices 30. In addition, the antennas 120a of the relay devices 120 may be each covered with a cover through which radio waves can be transmitted.

The through-holes 54a formed in the cover 54 are closed respectively by the antennas 120a of the relay devices 120. In addition, seal members may be interposed between the antennas 120a of the relay devices 120 and the upper surface of the cover 54.

The child-device-side wireless ICs 32 of the battery monitoring devices 30 are electrically connected respectively with the antennas 120a of the relay devices 120 by communication wiring provided in the shaft portions 120b of the relay devices 120. Consequently, wireless communication can be performed between the battery monitoring devices 30 and the battery control device 40 via the antennas 120a of the relay devices 120 and the parent-device-side antenna 43 of the battery control device 40.

In the present embodiment as well, diffuse reflection of radio waves occurs in the accommodation section 105. Therefore, the configurations of the battery monitoring systems described in the previous embodiments can also be applied to the present embodiment.

### Fourteenth Embodiment

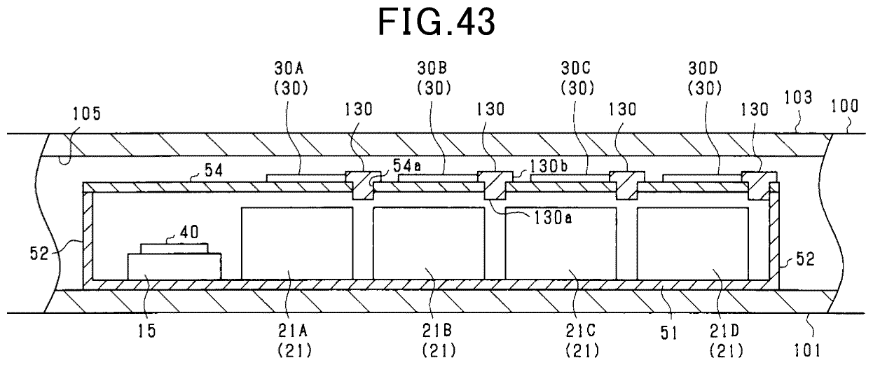

Hereinafter, a fourteenth embodiment will be described with reference to FIG. 43, focusing on the differences thereof from the thirteenth embodiment. It should be noted that for the sake of convenience, in FIG. 43, components identical or corresponding to those described in the previous embodiments are designated by the same reference signs as those described in the previous embodiments.

In the present embodiment, the battery control device 40 is mounted to the upper surface of the junction box 15 in the housing 50. On the other hand, the first to fourth battery monitoring devices 30A to 30D are located in the accommodation section 105 and outside the housing 50. More specifically, the first to fourth battery monitoring devices 30A to 30D are mounted to the upper surface of the cover 54. Therefore, in order to enable communication between the battery control device 40 accommodated in the housing 50 and the battery monitoring devices 30A to 30D located outside the housing 50, it is required to communicably connect the inside and outside of the housing 50.

To meet the above requirement, in the present embodiment, the battery pack 11 includes relay devices 130. Each of the relay devices 130 has a connection portion 130b located on the upper surface side of the cover 54 and an antenna 130a extending downward from the connection portion 130b. In the cover 54, there are formed through-holes 54a through which the antennas 130a of the relay devices 130 are respectively inserted into the housing 50. More particularly, in the present embodiment, the through-holes 54a are formed in the cover 54 so as to be aligned in a row in the longitudinal direction of the cover 54. Moreover, the relay devices 130 are provided individually to respectively correspond to the battery monitoring devices 30. In addition, the antennas 130a of the relay devices 130 may be each covered with a cover through which radio waves can be transmitted.

The through-holes 54a formed in the cover 54 are closed respectively by the connection portions 130b of the relay devices 130. In addition, seal members may be interposed between the connection portions 130b of the relay devices 130 and the upper surface of the cover 54.

The child-device-side wireless ICs 32 of the battery monitoring devices 30 are electrically connected respectively with the antennas 130a of the relay devices 130 by communication wiring provided in the connection portions 130b of the relay devices 130. Consequently, wireless communication can be performed between the battery monitoring devices 30 and the battery control device 40 via the antennas 130a of the relay devices 130 and the parent-device-side antenna 43 of the battery control device 40.

In the present embodiment as well, diffuse reflection of radio waves occurs in the accommodation section 105. Therefore, the configurations of the battery monitoring systems described in the previous embodiments can also be applied to the present embodiment.

### Fifteenth Embodiment

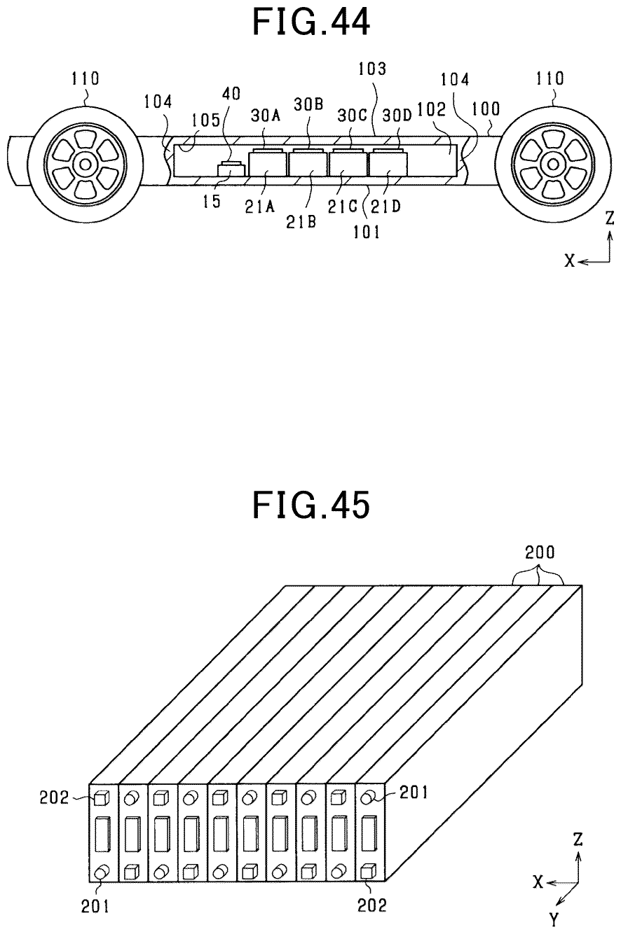

Hereinafter, a fifteenth embodiment will be described with reference to FIG. 44, focusing on the differences thereof from the previous embodiments. It should be noted that for the sake of convenience, in FIG. 44, components identical or corresponding to those described in the previous embodiments are designated by the same reference signs as those described in the previous embodiments.

In the present embodiment, as shown in FIG. 44, the battery pack 11 includes no housing 50. Moreover, the battery blocks 21A to 21D, the battery monitoring devices 30A to 30D and the battery control device 40 are accommodated directly in the accommodation section 105 of the chassis 100. Such a configuration of the battery pack 11 is called MTP (Module to Platform).

In the present embodiment as well, diffuse reflection of radio waves occurs in the accommodation section 105. Therefore, the configurations of the battery monitoring systems described in the previous embodiments can also be applied to the present embodiment.

### OTHER EMBODIMENTS

The above-described embodiments may also be implemented through the following modifications.

In the above-described embodiments, a configuration is employed in which: a plurality of battery blocks 21 are connected in series with each other; and each of the battery blocks 21 is constituted of a plurality of battery cells 22 that are connected in series with each other. Alternatively, a so-called CTP (Cell to Pack) configuration may be employed in which: a plurality of battery cells are connected in series with each other without forming battery blocks; and the battery cells are accommodated in the accommodation section 55 of the housing 50. FIG. 45 illustrates an example of the CTP configuration. In this example, a plurality of elongate battery cells 200, whose longitudinal directions coincide with the lateral direction of the vehicle 10, are accommodated in the accommodation section 55 of the housing 50. Moreover, for each adjacent pair of the battery cells 200, a positive-electrode terminal 201 of one of the pair of the battery cells 200 and a negative-electrode terminal 202 of the other of the pair of the battery cells 200 are electrically connected with each other by a busbar (not shown). In this case, a plurality of battery monitoring devices 30 may be provided individually to respectively correspond to the battery cells 200.

Moreover, instead of the CTP configuration, a so-called CTC (Cell to Chassis) configuration may be employed in which a plurality of battery cells are accommodated directly in the accommodation section 105 formed in the chassis 100 of the vehicle 10.

In the case of employing the CTP or CTC configuration, radio waves would be reflected by at least a part of the accommodation section. Therefore, advantageous effects can be achieved by applying the configurations of the battery monitoring systems described in the previous embodiments to this case.

The mobile object in which the battery monitoring system is installed is not limited to a vehicle, but may alternatively be, for example, an aircraft or a ship. Moreover, the control system is not limited to a system installed in a mobile object, but may alternatively be a stationary system.

The control unit and the control method described in the present disclosure may be realized by a dedicated computer that includes a processor, which is programmed to perform one or more functions embodied by a computer program, and a memory. As an alternative, the control unit and the control method described in the present disclosure may be realized by a dedicated computer that includes a processor configured with one or more dedicated hardware logic circuits. As another alternative, the control unit and the control method described in the present disclosure may be realized by one or more dedicated computers configured with a combination of a processor programmed to perform one or more functions, a memory and a processor configured with one or more dedicated hardware logic circuits. In addition, the computer program may be stored as computer-executable instructions in a computer-readable non-transitory tangible recording medium.

Hereinafter, characteristic configurations extracted from the above-described embodiments will be described.

### [First Configuration]

A battery control device (40) applicable to a battery monitoring system, the battery monitoring system comprising a plurality of battery monitoring devices (30, 30A to 30D) provided individually to respectively correspond to a plurality of batteries (21, 21A to 21D, 200) and monitor states of the corresponding batteries,
the battery control device being configured to be arranged, together with the batteries and the battery monitoring devices, in a predetermined arrangement state in an accommodation section (55, 105), the accommodation section being configured so that at least part of it reflects radio waves,
the battery control device comprising:
a parent-device-side storage unit (44) configured to store parameters related to communication quality of wireless communication between the battery monitoring devices and the battery control device when the batteries, the battery monitoring devices and the battery control device are arranged in the predetermined arrangement state in the accommodation section, the parameters being associated respectively with the battery monitoring devices;
a parent-device-side communication unit (42, 43) configured to perform the wireless communication with the battery monitoring devices; and
an identification unit (41) configured to perform an identification process of identifying, based on radio signals received from the battery monitoring devices by the parent-device-side communication unit and the parameters stored in the parent-device-side storage unit, the batteries monitored respectively by the battery monitoring devices that are respectively transmission sources of the received radio signals.

### [Second Configuration]

The battery control device according to the first configuration, wherein

the parameters are strengths of the radio signals received from the battery monitoring devices when the batteries, the battery monitoring devices and the battery control device are arranged in the predetermined arrangement state in the accommodation section.

### [Third Configuration]

The battery control device according to the second configuration, wherein
the identification unit is configured to perform, as the identification process, a process of:
calculating, for each of the battery monitoring devices, correlation coefficients between the strength of the radio signal received from the battery monitoring device by the parent-device-side communication unit and the parameters; and
identifying the battery that is monitored by the battery monitoring device associated with the parameter used for the calculation of a maximum correlation coefficient among the calculated correlation coefficients as a monitoring target of the battery monitoring device that is the transmission source of the radio signal used for the calculation of the maximum correlation coefficient.

### [Fourth Configuration]

The battery control device according to the third configuration, wherein

the identification unit is further configured to determine, based on the calculated correlation coefficients, whether an abnormality has occurred in which the arrangement state of the batteries, the battery monitoring devices and the battery control device in the accommodation section is deviated from the predetermined arrangement state.

### [Fifth Configuration]

The battery control device according to the second configuration, wherein

the identification unit is configured to perform, as the identification process, a process of identifying the batteries, which are monitored respectively by the battery monitoring devices, by comparing a magnitude relationship between the strengths of the radio signals received from the battery monitoring devices at a specific frequency with a magnitude relationship between the parameters associated respectively with the battery monitoring devices at the specific frequency.

### [Sixth Configuration]

The battery control device according to the second configuration, wherein
the identification unit is configured to perform, as the identification process, a process of:
calculating, for each of the battery monitoring devices, differences at a specific frequency between the strength of the radio signal received from the battery monitoring device by the parent-device-side communication unit and the parameters; and
identifying the battery that is monitored by the battery monitoring device associated with the parameter used for the calculation of a minimum difference among the calculated differences as a monitoring target of the battery monitoring device that is the transmission source of the radio signal used for the calculation of the minimum difference.

### [Seventh Configuration]

The battery control device according to the first configuration, wherein
the parameters are slopes of strengths of the radio signals received from the battery monitoring devices in a predetermined frequency range when the batteries, the battery monitoring devices and the battery control device are arranged in the predetermined arrangement state in the accommodation section, and
the identification unit is configured to perform, as the identification process, a process of:
calculating, for each of the battery monitoring devices, a slope of the strength of the radio signal received from the battery monitoring device by the parent-device-side communication unit in the predetermined frequency range;
calculating differences between the calculated slope and the parameters; and
identifying the battery that is monitored by the battery monitoring device associated with the parameter used for the calculation of a minimum difference among the calculated differences as a monitoring target of the battery monitoring device that is the transmission source of the radio signal used for the calculation of the slope.

### [Eighth Configuration]

The battery control device according to the first configuration, wherein
the parameters are average values of strengths of the radio signals received from the battery monitoring devices in a predetermined frequency range when the batteries, the battery monitoring devices and the battery control device are arranged in the predetermined arrangement state in the accommodation section, and
the identification unit is configured to perform, as the identification process, a process of:
calculating, for each of the battery monitoring devices, an average value of the strength of the radio signal received from the battery monitoring device by the parent-device-side communication unit in the predetermined frequency range;
calculating differences between the calculated average value and the parameters; and
identifying the battery that is monitored by the battery monitoring device associated with the parameter used for the calculation of a minimum difference among the calculated differences as a monitoring target of the battery monitoring device that is the transmission source of the radio signal used for the calculation of the average value.

### [Ninth Configuration]

The battery control device according to any one of the first to eighth configurations, wherein
the battery monitoring system is installed in a mobile object (10) which a user can ride, and
the identification unit is configured to perform the identification process on condition that no instruction to start the mobile object has been given by the user and the mobile object is in a stopped state.

### [Tenth Configuration]

The battery control device according to any one of the first to ninth configurations, wherein
the identification unit is further configured to:
identify, by the identification process, correspondence between the battery monitoring devices and the batteries that are monitored respectively by the battery monitoring devices; and
store information on the identified correspondence in the parent-device-side storage unit.

### [Eleventh Configuration]

A method of identifying, using the battery monitoring system comprising the battery control device according to the tenth configuration and the battery monitoring devices, an abnormal battery in which an abnormality has occurred among the batteries accommodated in the accommodation section,
wherein
each of the battery monitoring devices comprises a child-device-side communication unit (32, 33) configured to perform the wireless communication with the battery control device,
each of the battery monitoring devices is configured to:
determine whether an abnormality has occurred in a determination target that is at least one of the battery monitored by the battery monitoring device and the battery monitoring device itself; and
transmit, when it is determined that an abnormality has occurred in the determination target, information on the occurrence of the abnormality and identification information of the battery monitoring device from the child-device-side communication unit to the battery control device,
the battery control device is configured to:
receive the information on the occurrence of the abnormality and the identification information by the parent-device-side communication unit; and
store the received information on the occurrence of the abnormality in the parent-device-side storage unit,
the method comprising steps of:
connecting the battery control device and an inspection device so that they can communicate with each other;
reading, by the inspection device, the information on the correspondence and the information on the occurrence of the abnormality from the parent-device-side storage unit; and
causing the inspection device to identify, based on the information read from the parent-device-side storage unit, an abnormal battery in which the abnormality has occurred among the batteries accommodated in the accommodation section.

### [Twelfth Configuration]

A battery monitoring system comprising the battery control device according to any one of the first to ninth configurations and the battery monitoring devices, wherein
each of the battery monitoring devices comprises:
a child-device-side communication unit (32, 33) configured to perform the wireless communication with the battery control device; and
a child-device-side storage unit (34),
the identification unit is further configured to:
identify, by the identification process, correspondence between the battery monitoring devices and the batteries that are monitored respectively by the battery monitoring devices; and
transmit information on the identified correspondence from the parent-device-side communication unit to each of the battery monitoring devices,
each of the battery monitoring devices is configured to store, in the child-device-side storage unit thereof, the information on the correspondence received by the child-device-side communication unit thereof.

### [Thirteenth Configuration]

A battery monitoring system comprising the battery control device according to any one of the first to ninth configurations and the battery monitoring devices, wherein
each of the battery monitoring devices comprises a child-device-side communication unit (32, 33) including an antenna (33A to 33D, 60) and configured to perform the wireless communication with the battery control device, and
orientations of centers of radio wave directivity of the antennas of the child-device-side communication units of the battery monitoring devices are set so that frequency characteristics of the strengths of the radio signals received from the battery monitoring devices by the parent-device-side communication unit differ between the battery monitoring devices.

### [Fourteenth Configuration]

The battery monitoring system according to the thirteenth configuration, wherein
each of the antennas of the child-device-side communication units of the battery monitoring devices is configured so that the orientation of the center of radio wave directivity thereof can be selected from a plurality of orientations and set to the selected orientation, and
the parent-device-side storage unit of the battery control device is configured to store the parameters associated with the plurality of orientations as well as with the battery monitoring devices.

### [Fifteenth Configuration]

The battery monitoring system according to the thirteenth configuration, wherein
the parent-device-side communication unit of the battery control device includes an antenna (43),
the batteries (21A to 21D), the battery monitoring devices (30A to 30D), the battery control device and the accommodation section (55) are configured so that in plan view thereof, they are axisymmetric with respect to a reference axis (LP) that extends in a horizontal direction through the antenna of the parent-device-side communication unit,
two of the battery monitoring devices are arranged equidistantly from the battery control device in a direction in which the reference axis extends, and
the orientations of the centers of radio wave directivity of the antennas (33A to 33D) of the child-device-side communication units of the two battery monitoring devices are not axisymmetric with respect to the reference axis.

### [Sixteenth Configuration]

The battery monitoring system according to the thirteenth configuration, wherein
the parent-device-side communication unit of the battery control device includes an antenna (43),
the batteries (21A to 21D), the battery control device and the accommodation section (55) are configured so that in plan view thereof, they are axisymmetric with respect to a reference axis (LP) that extends in a horizontal direction through the antenna of the parent-device-side communication unit,
two of the battery monitoring devices are arranged respectively on opposite sides of the reference axis, and
the arrangement positions of the two battery monitoring devices are not axisymmetric with respect to the reference axis.

While the present disclosure has been described pursuant to the above embodiments, it should be appreciated that the present disclosure is not limited to the embodiments and the structures. Instead, the present disclosure encompasses various modifications and changes within equivalent ranges. In addition, various combinations and modes are also included in the category and the scope of technical idea of the present disclosure.

What is claimed is:

1. A battery control device applicable to a battery monitoring system, the battery monitoring system comprising a plurality of battery monitoring devices provided individually to respectively correspond to a plurality of batteries and monitor states of the corresponding batteries,
the battery control device being configured to be arranged, together with the batteries and the battery monitoring devices, in a predetermined arrangement state in an accommodation section, the accommodation section being configured so that at least part of it reflects radio waves,
the battery control device comprising:
a parent-device-side storage unit configured to store parameters related to communication quality of wireless communication between the battery monitoring devices and the battery control device when the batteries, the battery monitoring devices and the battery control device are arranged in the predetermined arrangement state in the accommodation section, the parameters being associated respectively with the battery monitoring devices;
a parent-device-side communication unit configured to perform the wireless communication with the battery monitoring devices; and
an identification unit configured to perform an identification process of identifying, based on radio signals received from the battery monitoring devices by the parent-device-side communication unit and the parameters stored in the parent-device-side storage unit, the batteries monitored respectively by the battery monitoring devices that are respectively transmission sources of the received radio signals.

2. The battery control device as set forth in claim 1, wherein
the parameters are strengths of the radio signals received from the battery monitoring devices when the batteries, the battery monitoring devices and the battery control device are arranged in the predetermined arrangement state in the accommodation section.

3. The battery control device as set forth in claim 2, wherein
the identification unit is configured to perform, as the identification process, a process of:
calculating, for each of the battery monitoring devices, correlation coefficients between the strength of the radio signal received from the battery monitoring device by the parent-device-side communication unit and the parameters; and
identifying the battery that is monitored by the battery monitoring device associated with the parameter used for the calculation of a maximum correlation coefficient among the calculated correlation coefficients as a monitoring target of the battery monitoring device that is the transmission source of the radio signal used for the calculation of the maximum correlation coefficient.

4. The battery control device as set forth in claim 3, wherein
the identification unit is further configured to determine, based on the calculated correlation coefficients, whether an abnormality has occurred in which the arrangement state of the batteries, the battery monitoring devices and the battery control device in the accommodation section is deviated from the predetermined arrangement state.

5. The battery control device as set forth in claim 2, wherein
the identification unit is configured to perform, as the identification process, a process of identifying the batteries, which are monitored respectively by the battery monitoring devices, by comparing a magnitude relationship between the strengths of the radio signals received from the battery monitoring devices at a specific frequency with a magnitude relationship between the parameters associated respectively with the battery monitoring devices at the specific frequency.

6. The battery control device as set forth in claim 2, wherein
the identification unit is configured to perform, as the identification process, a process of:
calculating, for each of the battery monitoring devices, differences at a specific frequency between the strength of the radio signal received from the battery monitoring device by the parent-device-side communication unit and the parameters; and
identifying the battery that is monitored by the battery monitoring device associated with the parameter used for the calculation of a minimum difference among the calculated differences as a monitoring target of the battery monitoring device that is the transmission source of the radio signal used for the calculation of the minimum difference.

7. The battery control device as set forth in claim 1, wherein
the parameters are slopes of strengths of the radio signals received from the battery monitoring devices in a predetermined frequency range when the batteries, the battery monitoring devices and the battery control device are arranged in the predetermined arrangement state in the accommodation section, and
the identification unit is configured to perform, as the identification process, a process of:
calculating, for each of the battery monitoring devices, a slope of the strength of the radio signal received from the battery monitoring device by the parent-device-side communication unit in the predetermined frequency range;
calculating differences between the calculated slope and the parameters; and
identifying the battery that is monitored by the battery monitoring device associated with the parameter used for the calculation of a minimum difference among the calculated differences as a monitoring target of the battery monitoring device that is the transmission source of the radio signal used for the calculation of the slope.

8. The battery control device as set forth in claim 1, wherein
the parameters are average values of strengths of the radio signals received from the battery monitoring devices in a predetermined frequency range when the batteries, the battery monitoring devices and the battery control device are arranged in the predetermined arrangement state in the accommodation section, and
the identification unit is configured to perform, as the identification process, a process of:
calculating, for each of the battery monitoring devices, an average value of the strength of the radio signal received from the battery monitoring device by the parent-device-side communication unit in the predetermined frequency range;
calculating differences between the calculated average value and the parameters; and
identifying the battery that is monitored by the battery monitoring device associated with the parameter used for the calculation of a minimum difference among the calculated differences as a monitoring target of the battery monitoring device that is the transmission source of the radio signal used for the calculation of the average value.

9. The battery control device as set forth in claim 1, wherein
the battery monitoring system is installed in a mobile object which a user can ride, and
the identification unit is configured to perform the identification process on condition that no instruction to start the mobile object has been given by the user and the mobile object is in a stopped state.

10. The battery control device as set forth in claim 1, wherein
the identification unit is further configured to:
identify, by the identification process, correspondence between the battery monitoring devices and the batteries that are monitored respectively by the battery monitoring devices; and
store information on the identified correspondence in the parent-device-side storage unit.

11. A method of identifying, using the battery monitoring system comprising the battery control device as set forth in claim 10 and the battery monitoring devices, an abnormal battery in which an abnormality has occurred among the batteries accommodated in the accommodation section,
wherein
each of the battery monitoring devices comprises a child-device-side communication unit configured to perform the wireless communication with the battery control device,
each of the battery monitoring devices is configured to:
determine whether an abnormality has occurred in a determination target that is at least one of the battery monitored by the battery monitoring device and the battery monitoring device itself, and
transmit, when it is determined that an abnormality has occurred in the determination target, information on the occurrence of the abnormality and identification information of the battery monitoring device from the child-device-side communication unit to the battery control device,
the battery control device is configured to:
receive the information on the occurrence of the abnormality and the identification information by the parent-device-side communication unit; and
store the received information on the occurrence of the abnormality in the parent-device-side storage unit,
the method comprising steps of:
connecting the battery control device and an inspection device so that they can communicate with each other;
reading, by the inspection device, the information on the correspondence and the information on the occurrence of the abnormality from the parent-device-side storage unit; and
causing the inspection device to identify, based on the information read from the parent-device-side storage unit, an abnormal battery in which the abnormality has occurred among the batteries accommodated in the accommodation section.

12. A battery monitoring system comprising the battery control device as set forth in claim 1 and the battery monitoring devices, wherein
each of the battery monitoring devices comprises:
a child-device-side communication unit configured to perform the wireless communication with the battery control device; and
a child-device-side storage unit,
the identification unit is further configured to:
identify, by the identification process, correspondence between the battery monitoring devices and the batteries that are monitored respectively by the battery monitoring devices; and
transmit information on the identified correspondence from the parent-device-side communication unit to each of the battery monitoring devices,
each of the battery monitoring devices is configured to store, in the child-device-side storage unit thereof, the information on the correspondence received by the child-device-side communication unit thereof.

13. A battery monitoring system comprising the battery control device as set forth in claim 1 and the battery monitoring devices, wherein
each of the battery monitoring devices comprises a child-device-side communication unit including an antenna and configured to perform the wireless communication with the battery control device, and
orientations of centers of radio wave directivity of the antennas of the child-device-side communication units of the battery monitoring devices are set so that frequency characteristics of the strengths of the radio signals received from the battery monitoring devices by the parent-device-side communication unit differ between the battery monitoring devices.

14. The battery monitoring system as set forth in claim 13, wherein
each of the antennas of the child-device-side communication units of the battery monitoring devices is configured so that the orientation of the center of radio wave directivity thereof can be selected from a plurality of orientations and set to the selected orientation, and
the parent-device-side storage unit of the battery control device is configured to store the parameters associated with the plurality of orientations as well as with the battery monitoring devices.

15. The battery monitoring system as set forth in claim 13, wherein
the parent-device-side communication unit of the battery control device includes an antenna,
the batteries, the battery monitoring devices, the battery control device and the accommodation section are configured so that in plan view thereof, they are axisymmetric with respect to a reference axis that extends in a horizontal direction through the antenna of the parent-device-side communication unit,
two of the battery monitoring devices are arranged equidistantly from the battery control device in a direction in which the reference axis extends, and
the orientations of the centers of radio wave directivity of the antennas of the child-device-side communication units of the two battery monitoring devices are not axisymmetric with respect to the reference axis.

16. The battery monitoring system as set forth in claim 13, wherein
the parent-device-side communication unit of the battery control device includes an antenna,
the batteries, the battery control device and the accommodation section are configured so that in plan view thereof, they are axisymmetric with respect to a reference axis that extends in a horizontal direction through the antenna of the parent-device-side communication unit,
two of the battery monitoring devices are arranged respectively on opposite sides of the reference axis, and
the arrangement positions of the two battery monitoring devices are not axisymmetric with respect to the reference axis.
